(19) United States
(12) Patent Application Publication
(10) Pub. No.: US 2025/0204044 A1
(43) Pub. Date: Jun. 19, 2025

(54) ARRAY SUBSTRATE, DISPLAY DEVICE, AND METHOD FOR MANUFACTURING ARRAY SUBSTRATE

(71) Applicant: Sharp Display Technology Corporation, Kameyama City (JP)

(72) Inventors: Atsushi HACHIYA, Kameyama City (JP); Yuhichi Saitoh, Kameyama City (JP); Hiroaki Furukawa, Kameyama City (JP)

(21) Appl. No.: 18/956,369

(22) Filed: Nov. 22, 2024

(30) Foreign Application Priority Data
Dec. 18, 2023 (JP) 2023-212982

(51) Int. Cl. H10D 86/01; H10D 86/40; H10D 86/60

(52) U.S. Cl. CPC H10D 86/441; H10D 86/0221; H10D 86/423; H10D 86/60

(57) ABSTRACT

There is provided an array substrate including a first electrode constituted by a first conductive film, a first insulating film disposed on a lower layer side of the first conductive film, a first conductivity-induced portion formed by making a portion of a semiconductor film disposed on a lower layer side of the first insulating film conductive, the portion not overlapping the first electrode, a second conductivity-induced portion formed by making a portion of the semiconductor film other than the first conductivity-induced portion conductive, the portion not overlapping the first electrode, a first semiconductor portion constituted by a portion of the semiconductor film overlapping the first electrode, and an intervening portion constituted by a portion of the first conductive film other than the first electrode or a part of the first insulating film, the intervening portion being disposed between the first conductivity-induced portion and the second conductivity-induced portion.

### CROSS-REFERENCE TO RELATED APPLICATIONS

This application claims the benefit of priority to Japanese Patent Application Number 2023-212982 filed on Dec. 18, 2023. The entire contents of the above-identified application are hereby incorporated by reference.

### BACKGROUND

### Technical Field

The technology disclosed herein relates to an array substrate, a display device, and a method for manufacturing an array substrate.

In the related art, as an example of a display device including an array substrate, there is known a display device described in JP 2008-175842 A. In the display device disclosed in JP 2008-175842, a transparent oxide layer and a metal layer are formed such that one of the transparent oxide layer and the metal layer serves as an upper layer in a pixel region on a substrate, an insulating film and a conductive layer are sequentially layered on the one of the transparent oxide layer and the metal layer, the conductive layer includes a gate electrode of a thin film transistor connected to a gate signal line, the metal layer constitutes a source signal line, and the transparent oxide layer is made conductive at least in a region other than a channel region immediately below the gate electrode, and constitutes a source region of the thin film transistor connected to the source signal line, a pixel electrode, and a drain region of the thin film transistor connected to the pixel electrode in the portion made conductive.

### SUMMARY

As described above, in the display device described in JP 2008-175842 A, the source region, the pixel electrode, and the drain region are constituted by the portion made conductive of the transparent oxide layer. For this reason, when an arrangement pitch of pixels becomes narrower as the definition of the display device becomes higher, for example, two source regions constituting adjacent pixels to each other may be short-circuited due to a film residue that may be generated in patterning the transparent oxide layer.

The techniques described herein have been made based on the circumstances described above, and an object thereof is to suppress the occurrence of a short circuit.

(1) According to a technique described herein, there is provided an array substrate including a first electrode constituted by a first conductive film, a first insulating film disposed on a lower layer side of the first conductive film, a first conductivity-induced portion formed by making a portion of a semiconductor film disposed on a lower layer side of the first insulating film conductive, the portion not overlapping the first electrode, a second conductivity-induced portion formed by making a portion of the semiconductor film other than the first conductivity-induced portion conductive, the portion not overlapping the first electrode, a first semiconductor portion constituted by a portion of the semiconductor film overlapping the first electrode, and an intervening portion constituted by a portion of the first conductive film other than the first electrode or a part of the first insulating film, the intervening portion being disposed between the first conductivity-induced portion and the second conductivity-induced portion.

(2) In addition to (1) described above, in the array substrate, the first insulating film may include a first insulating portion overlapping the first electrode and the first semiconductor portion, and the intervening portion may be constituted by a portion of the first insulating film other than the first insulating portion.

(3) In addition to (2) described above, in the array substrate, the semiconductor film may be made of an oxide semiconductor material, a second insulating film may be provided on an upper layer side of the first conductive film and include a reducing agent, the second insulating film may be in contact with the first conductivity-induced portion and the second conductivity-induced portion, the first insulating film may include a second insulating portion being continuous with the first insulating portion and not overlapping the first electrode and the first semiconductor portion, and a first high-resistance portion constituted by a portion of the semiconductor film overlapping the second insulating portion may be provided, and the first high-resistance portion may be continuous with the first conductivity-induced portion and have a resistance higher than a resistance of the first conductivity-induced portion.

(4) In addition to (3) described above, in the array substrate, a distance from an end portion of the intervening portion on the first conductivity-induced portion side to an end portion of the intervening portion on the second conductivity-induced portion side may be larger than a distance from an end portion of the first high-resistance portion on the first semiconductor portion side to an end portion of the first high-resistance portion on the first conductivity-induced portion side.

(5) In addition to any one of (2) to (4) described above, the array substrate may further include a first wiring line constituted by the first conductive film, extending along a first direction, and including the first electrode, and a first linear insulating portion constituted by the first insulating film, extending along the first direction, overlapping the first wiring line, and including the first insulating portion, the first conductivity-induced portion and the second conductivity-induced portion may intersect the first wiring line and the first linear insulating portion, and the intervening portion may be continuous with the first linear insulating portion.

(6) In addition to (5) described above, the array substrate may further include a second wiring line made of the first conductive film, disposed at a position spaced apart from the first wiring line in a second direction intersecting the first direction, and extending along the first direction, and a second linear insulating portion constituted by the first insulating film, extending along the first direction, and overlapping the second wiring line, and the intervening portion may be continuous with the second linear insulating portion.

(7) In addition to (1) described above, in the array substrate, the first conductive film may be made of a metal material, and the intervening portion may be constituted by a portion of the first conductive film other than the first electrode.

(8) In addition to any one of (1) to (7) described above, the array substrate may further include a second insulating film disposed on an upper layer side of the first conductive film, a third wiring line constituted by the second conductive film disposed on an upper layer side of the second insulating film and partially overlapping the first conductivity-induced portion, and a fourth wiring line constituted by a portion of the second conductive film other than the third wiring line and partially overlapping the second conductivity-induced portion, a first contact hole connecting the third wiring line and the first conductivity-induced portion may be provided at a position of the second insulating film overlapping both the third wiring line and the first conductivity-induced portion, and a second contact hole connecting the fourth wiring line and the second conductivity-induced portion may be provided at a position of the second insulating film overlapping both the fourth wiring line and the second conductivity-induced portion.

(9) In addition to (8) described above, in the array substrate, the third wiring line and the fourth wiring line may be parallel to each other, the first conductivity-induced portion may include a first inclined portion inclined relative to the third wiring line and the fourth wiring line, the second conductivity-induced portion may include a second inclined portion parallel to the first inclined portion, and the intervening portion may include a third inclined portion parallel to the first inclined portion and the second inclined portion.

(10) In addition to (8) or (9) described above, in the array substrate, the first conductivity-induced portion may partially overlap the first contact hole and thus does not overlap a portion of the first contact hole on the second conductivity-induced portion side.

(11) According to the technique described herein, there is provided a display device including the array substrate described in any one of (1) to (10) described above, and a counter substrate facing the array substrate.

(12) According to the technique described herein, there is provided a method for manufacturing an array substrate including forming a semiconductor film made of an oxide semiconductor material, patterning the semiconductor film, and thus providing a first non-conductivity-induced portion, a second non-conductivity-induced portion spaced apart from the first non-conductivity-induced portion, and a first semiconductor portion, forming a first insulating film on an upper layer side of the semiconductor film, forming a first conductive film on an upper layer side of the first insulating film, patterning the first conductive film, and thus providing a first electrode overlapping the first semiconductor portion, patterning the first insulating film, and thus providing a first insulating portion overlapping the first electrode and the first semiconductor portion and an intervening portion disposed between the first non-conductivity-induced portion and the second non-conductivity-induced portion, and forming a second insulating film including a reducing agent on an upper layer side of the first conductive film, bringing the second insulating film into contact with the first non-conductivity-induced portion and the second non-conductivity-induced portion, making the first non-conductivity-induced portion and the second non-conductivity-induced portion conductive, and thus changing the first non-conductivity-induced portion and the second non-conductivity-induced portion into a first conductivity-induced portion and a second conductivity-induced portion, respectively.

(13) In addition to (12) described above, the method for manufacturing the array substrate may further include patterning the first insulating film, and thus providing a second insulating portion not overlapping the first electrode and the first semiconductor portion and being continuous with the first insulating portion, and patterning the semiconductor film, and thus providing a third non-conductivity-induced portion overlapping the second insulating portion and being continuous with the first non-conductivity-induced portion, and in the forming of the second insulating film, the third non-conductivity-induced portion becomes a first high-resistance portion having a resistance higher than a resistance of the first conductivity-induced portion.

(14) In addition to (13) described above, in the method for manufacturing the array substrate, the first insulating film may be patterned after the first conductive film is patterned.

(15) According to the technique described herein, there is provided a method for manufacturing an array substrate including forming a semiconductor film, patterning the semiconductor film, and thus providing a first non-conductivity-induced portion, a second non-conductivity-induced portion spaced apart from the first non-conductivity-induced portion, and a first semiconductor portion, forming a first insulating film on an upper layer side of the semiconductor film, forming a first conductive film on an upper layer side of the first insulating film, patterning the first conductive film, and thus providing a first electrode overlapping the first semiconductor portion and an intervening portion disposed between the first non-conductivity-induced portion and the second non-conductivity-induced portion, and performing a conductive treatment on the semiconductor film by using the first conductive film as a mask and making the semiconductor film conductive, and making the first non-conductivity-induced portion and the second non-conductivity-induced portion not overlapping the first electrode and the intervening portion conductive, and thus changing the first non-conductivity-induced portion and the second non-conductivity-induced portion into a first conductivity-induced portion and a second conductivity-induced portion, respectively.

According to the techniques described herein, the occurrence of a short circuit can be suppressed.

### BRIEF DESCRIPTION OF DRAWINGS

The disclosure will be described with reference to the accompanying drawings, wherein like numbers reference like elements.

FIG. 1 is a schematic perspective view illustrating a state in which a head-mounted display according to a first embodiment is worn on the head by a user.

FIG. 2 is a schematic side view illustrating an optical relationship between a liquid crystal display device and a lens unit provided in a head-mounted device included in the head-mounted display according to the first embodiment, and an eyeball of the user.

FIG. 3 is a schematic plan view illustrating a liquid crystal panel and a flexible substrate provided in the liquid crystal display device according to the first embodiment.

FIG. 4 is a schematic cross-sectional view of the liquid crystal panel according to the first embodiment.

FIG. 5 is a plan view illustrating a pixel arrangement in a display region of an array substrate provided in the liquid crystal panel according to the first embodiment.

FIG. 6 is a cross-sectional view of the array substrate according to the first embodiment taken along line vi-vi in FIG. 5.

FIG. 7 is a cross-sectional view of the array substrate according to the first embodiment taken along line vii-vii in FIG. 5.

FIG. 8 is a plan view illustrating a state in which a film residue is generated at a semiconductor film in the display region of the array substrate according to the first embodiment.

FIG. 9 is a cross-sectional view, similar to FIG. 7, illustrating a state in which the film residue is generated at the semiconductor film in the display region of the array substrate according to the first embodiment.

FIG. 10 is a flowchart illustrating a procedure of processes of a method for manufacturing an array substrate according to the first embodiment.

FIG. 11 is a cross-sectional view, similar to FIG. 6, illustrating a state before etching a second metal film through a first photoresist film in second metal film patterning included in the method for manufacturing the array substrate according to the first embodiment.

FIG. 12 is a cross-sectional view, similar to FIG. 6, illustrating a state before etching an upper-layer side gate insulating film through a second photoresist film in upper-layer side gate insulating film patterning included in the method for manufacturing the array substrate according to the first embodiment.

FIG. 13 is a cross-sectional view, similar to FIG. 6, illustrating a state in which the upper-layer side gate insulating film has been etched through the upper-layer side gate insulating film patterning included in the method for manufacturing the array substrate according to the first embodiment.

FIG. 14 is a cross-sectional view, similar to FIG. 7, illustrating a state in which the upper-layer side gate insulating film has been etched through the upper-layer side gate insulating film patterning included in the method for manufacturing the array substrate according to the first embodiment.

FIG. 15 is a cross-sectional view, similar to FIG. 7, illustrating a state in which the upper-layer side gate insulating film has been etched through the upper-layer side gate insulating film patterning included in the method for manufacturing the array substrate according to the first embodiment, and illustrating a state in which the film residue has been generated at the semiconductor film.

FIG. 16 is a cross-sectional view, similar to FIG. 6, illustrating a state before etching the upper-layer side gate insulating film through the second photoresist film in the upper-layer side gate insulating film patterning included in the method for manufacturing the array substrate according to the first embodiment, and illustrating a state in which the film residue has been generated at the second metal film.

FIG. 17 is a cross-sectional view, similar to FIG. 6, illustrating a state in which the upper-layer side gate insulating film has been etched through the upper-layer side gate insulating film patterning included in the method for manufacturing the array substrate according to the first embodiment, and illustrating a state in which the film residue has been generated at the second metal film.

FIG. 18 is a plan view illustrating a pixel arrangement in a display region of an array substrate provided in a liquid crystal panel according to a second embodiment.

FIG. 19 is a plan view illustrating a state in which a film residue has been generated at a semiconductor film in the display region of the array substrate according to the second embodiment.

FIG. 20 is a cross-sectional view of the array substrate according to the second embodiment taken along line xx-xx in FIG. 19.

FIG. 21 is a plan view illustrating a pixel arrangement in a display region of an array substrate provided in a liquid crystal panel according to a third embodiment.

FIG. 22 is a plan view illustrating a state in which a film residue of a semiconductor film has been generated in the display region of the array substrate according to the third embodiment.

FIG. 23 is a cross-sectional view of the array substrate according to the third embodiment taken along line xxiii-xxiii in FIG. 22.

FIG. 24 is a plan view illustrating a pixel arrangement in a display region of an array substrate provided in a liquid crystal panel according to a fourth embodiment.

FIG. 25 is a plan view illustrating a pixel arrangement in a display region of an array substrate provided in a liquid crystal panel according to a fifth embodiment.

FIG. 26 is a plan view illustrating a pixel arrangement in a display region of an array substrate provided in a liquid crystal panel according to a sixth embodiment.

FIG. 27 is a plan view illustrating a pixel arrangement in a display region of an array substrate provided in a liquid crystal panel according to a seventh embodiment.

FIG. 28 is a plan view illustrating a pixel arrangement in a display region of an array substrate provided in a liquid crystal panel according to an eighth embodiment.

FIG. 29 is a cross-sectional view, similar to FIG. 6, of an array substrate according to a ninth embodiment.

FIG. 30 is a plan view illustrating a state in which a film residue has been generated at a semiconductor film in a display region of the array substrate according to the ninth embodiment.

FIG. 31 is a cross-sectional view of the array substrate according to the ninth embodiment taken along line xxxi-xxxi in FIG. 30.

FIG. 32 is a flowchart illustrating a procedure of processes of a method for manufacturing an array substrate according to the ninth embodiment.

FIG. 33 is a cross-sectional view, similar to FIG. 29, illustrating a state before performing a conductive treatment on a semiconductor film in a process of performing the conductive treatment included in the method for manufacturing the array substrate according to the ninth embodiment.

FIG. 34 is a cross-sectional view, similar to FIG. 29, illustrating a state in which the conductive treatment has been performed on the semiconductor film in the process of performing the conductive treatment included in the method for manufacturing the array substrate according to the ninth embodiment.

FIG. 35 is a cross-sectional view, similar to FIG. 31, illustrating a state in which the upper-layer side gate insulating film has been etched through a process of patterning an upper-layer side gate insulating film included in the method for manufacturing the array substrate according to the ninth embodiment, and illustrating a state in which a film residue of the semiconductor film has been generated.

### DESCRIPTION OF EMBODIMENTS

### First Embodiment

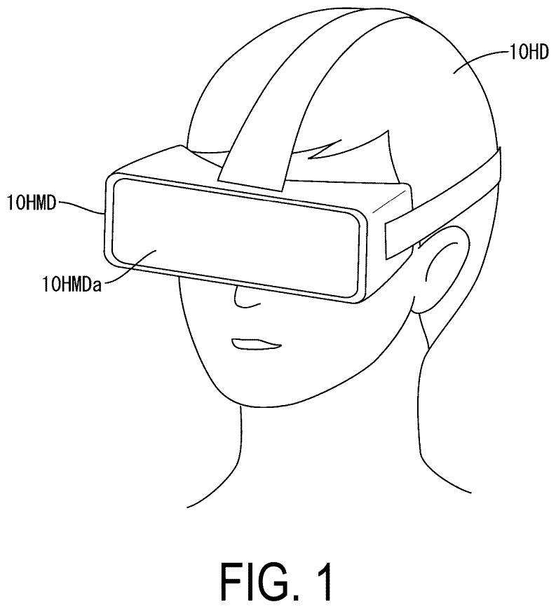

A first embodiment will be described with reference to FIG. 1 to FIG. 17. In the present embodiment, a goggle-type head-mounted display (Head-Mounted Display: HMD) 10HMD and a liquid crystal display device (display device) 10 used for the head-mounted display are exemplified. Note that some drawings illustrate an X-axis, a Y-axis, and a Z-axis, and directions of these axes are drawn so as to be common in all the drawings.

The appearance of the goggle-type head-mounted display 10HMD will be described with reference to FIG. 1. As illustrated in FIG. 1, the head-mounted display 10HMD includes a head-mounted device 10HMDa mounted on the head 10HD of a user. The head-mounted device 10HMDa surrounds both eyes of the user.

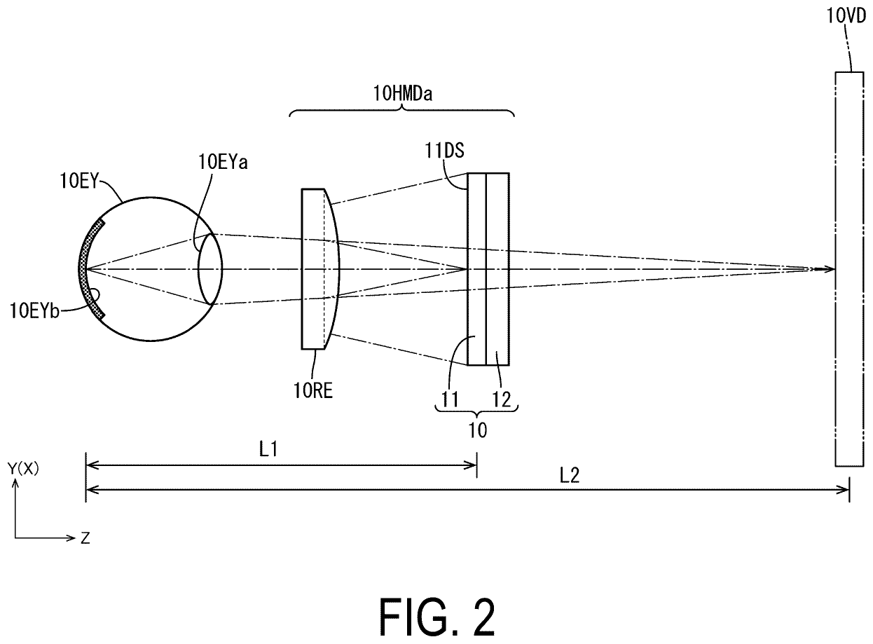

A configuration of the head-mounted device 10HMDa will be described with reference to FIG. 2. As illustrated in FIG. 2, the head-mounted device 10HMDa incorporates at least a liquid crystal display device 10 configured to display an image and a lens unit 10RE configured to focus the image displayed on the liquid crystal display device 10 on an eyeball 10EY of the user. The liquid crystal display device 10 includes at least a liquid crystal panel (display device) 11 and a backlight device (illumination device) 12 configured to irradiate the liquid crystal panel 11 with light. A main surface of the liquid crystal panel 11 on the lens unit 10RE side is a display surface 11DS that displays the image. The lens unit 10RE is interposed between the liquid crystal display device 10 and the eyeball 10EY of the user. The lens unit 10RE imparts a refracting action to light. By adjusting a focal length of the lens unit 10RE, the user can recognize that an image focused on a retina 10EYb through a crystalline lens 10EYa of the eyeball 10EY is displayed on a virtual display 10VD that is apparently present at a position of a distance L2 from the eyeball 10EY. This distance L2 is much larger than an actual distance L1 from the eyeball 10EY to the liquid crystal display device 10. As a result, the user can visually recognize an enlarged image that is a virtual image displayed on the virtual display 10VD having a screen size (for example, from about several tens of inches to about several hundreds of inches) much larger than a screen size (for example, from about 0. several inches to about several inches) of the liquid crystal display device 10.

By mounting one liquid crystal display device 10 on the head-mounted device 10HMDa, an image for a right eye and an image for a left eye can be displayed on the liquid crystal display device 10. Alternatively, by mounting two liquid crystal display devices 10 on the head-mounted device 10HMDa, the image for the right eye and the image for the left eye may be displayed on one of the liquid crystal display devices 10 and on the other of the liquid crystal display devices 10, respectively. The head-mounted device 10HMDa may be provided with earphones or the like that are put to the ears of the user and emit a sound.

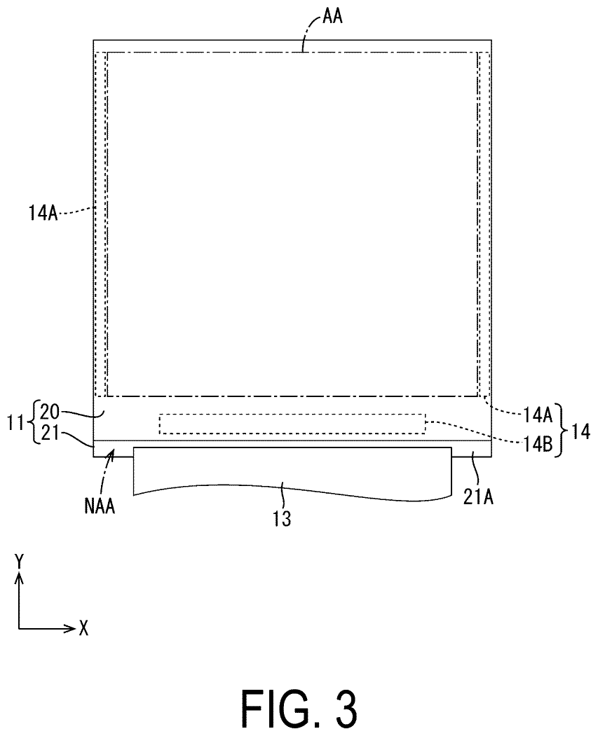

A configuration of the liquid crystal panel 11 included in the liquid crystal display device 10 will be described with reference to FIG. 3 and the like. Note that the configuration of the backlight device 12 is as known, and includes, for example, a light source such as an LED, an optical member that converts light from the light source into planar light by applying an optical effect to the light from the light source, and the like. As illustrated in FIG. 3, the liquid crystal panel 11 has a rectangular shape as a whole in plan view. A center-side portion of the screen of the liquid crystal panel 11 is a display region AA in which an image is displayed. A frame-shaped outer peripheral portion surrounding the display region AA of the screen of the liquid crystal panel 11 is a non-display region NAA in which no image is displayed. A range surrounded by an alternating dotted-dashed line in FIG. 3 is the display region AA. The liquid crystal panel 11 according to the present embodiment is used in the head-mounted display 10HMD described above and thus has an extremely high definition, with a pixel density thereof being, for example, about 1000 ppi or more.

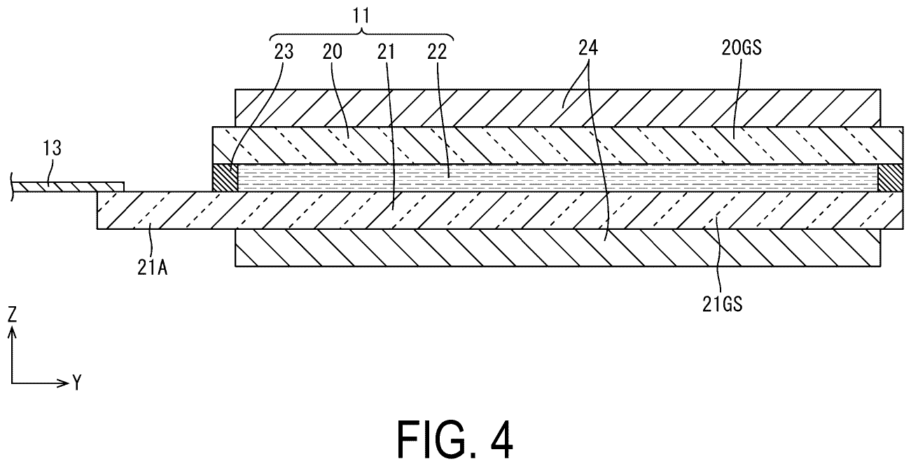

As illustrated in FIG. 4, the liquid crystal panel 11 is formed by bonding a pair of substrates 20 and 21 together. Of the pair of substrates 20 and 21, one disposed on a front side is a counter substrate (second substrate, CF substrate) 20, and the other one disposed on a back side is an array substrate (first substrate, active matrix substrate) 21. The counter substrate 20 and the array substrate 21 are each formed by layering various films on an inner face side of a respective one of glass substrates 20GS and 21GS that are substantially transparent and have excellent light-transmittance. The substrates 20GS and 21GS contain, for example, alkali-free glass as a main material. The array substrate 21 is larger than the counter substrate 20, and part of the array substrate 21 protrudes laterally relative to the counter substrate 20. A flexible substrate 13 is mounted on a protruding portion 21A of the array substrate 21. The flexible substrate 13 has a configuration in which a plurality of wiring line patterns are formed on a flexible base material having insulating properties. One end side of the flexible substrate 13 is connected to the array substrate 21, and the other end side thereof is connected to an external control substrate (signal supply source). Various signals supplied from the control substrate are transmitted to the liquid crystal panel 11 via the flexible substrate 13.

As illustrated in FIG. 3, a circuit portion (peripheral circuit portion) 14 is provided in the non-display region NAA of the liquid crystal panel 11. The circuit portion 14 includes a first circuit portion 14A and a second circuit portion 14B. A pair of the first circuit portions 14A are disposed sandwiching the display region AA from both sides in an X-axis direction. The first circuit portion 14A is provided in a belt-shaped range extending along a Y-axis direction. The first circuit portion 14A is configured to supply a scanning signal to each of gate wiring lines 25 and 29, which will be described later, and monolithically provided on the array substrate 21. The first circuit portion 14A is a Gate Driver Monolithic (GDM) circuit. The first circuit portion 14A includes a shift register circuit configured to output the scanning signal at a predetermined timing, a buffer circuit for amplifying the scanning signal, and the like. The second circuit portion 14B is disposed at a position interposed between the display region AA and the flexible substrate 13 in the Y-axis direction. The second circuit portion 14B is provided in a belt-shaped range extending along the X-axis direction. The second circuit portion 14B is configured to supply an image signal (data signal) to each of source wiring lines 26, which will be described later, and monolithically provided on the array substrate 21. The second circuit portion 14B includes a Source Shared Driving (SSD) circuit and the like. The second circuit portion 14B has a switching function of distributing an image signal supplied by the flexible substrate 13 to each source wiring line 26 or the like. Similarly to the first circuit portion 14A, the second circuit portion 14B may overlap the counter substrate 20.

Next, a schematic cross-sectional configuration of the liquid crystal panel 11 will be described with reference to FIG. 4. As illustrated in FIG. 4, the pair of substrates 20 and 21 are disposed to face each other at an interval in a Z-axis direction that is the normal direction of main surfaces of the substrates 20 and 21. At least a liquid crystal layer 22 and a sealing portion 23 sealing the liquid crystal layer 22 are each interposed between the pair of substrates 20 and 21. The liquid crystal layer 22 contains liquid crystal molecules that serve as a substance having optical characteristics changing according to an applied electrical field. The sealing portion 23 has a rectangular frame-like shape (endless ring shape) as a whole in plan view, and surrounds over the entire periphery of the liquid crystal layer 22 in the non-display region NAA. A gap (cell gap) corresponding to a thickness of the liquid crystal layer 22 is maintained by the sealing portion 23. Note that each of polarizers 24 is bonded to a respective one of outer face sides of the pair of substrates 20 and 21.

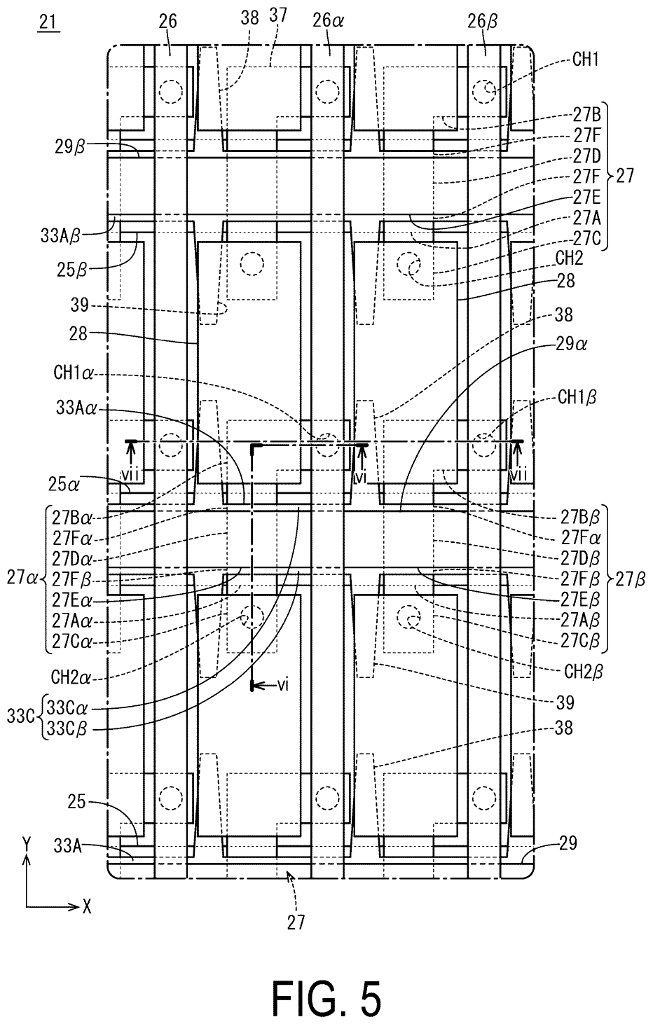

An overview of a pixel arrangement in the display region AA of the array substrate 21 will now be described with reference to FIG. 5. A plurality of lower-layer side gate wiring lines (lower-layer side scanning wiring lines) 25, a plurality of upper-layer side gate wiring lines (first wiring lines, second wiring lines, and upper-layer side scanning wiring lines) 29, and a plurality of source wiring lines (third wiring lines, fourth wiring lines, and image wiring lines) 26 are disposed on the inner face side of the display region AA of the array substrate 21 as illustrated in FIG. 5. Each of the lower-layer side gate wiring lines 25 and each of the upper-layer side gate wiring lines 29 extend along the X-axis direction (a first direction) to cross the display region AA, and overlap each other. The upper-layer side gate wiring line 29 has a line width narrower than that of the lower-layer side gate wiring line 25. Both side edges of the lower-layer side gate wiring line 25 protrude to both sides in the Y-axis direction relative to both side edges of the upper-layer side gate wiring line 29. Note that the lower-layer side gate wiring line 25 and the upper-layer side gate wiring line 29 may be disposed such that the centers thereof in a width direction (Y-axis direction) coincide with each other, but may be disposed such that the centers thereof are shifted from each other. The plurality of lower-layer side gate wiring lines 25 and the plurality of upper-layer side gate wiring lines 29 are disposed side by side at intervals in the Y-axis direction. The scanning signal output from the first circuit portion 14A described above is supplied to each of the plurality of lower-layer side gate wiring lines 25 and the plurality of upper-layer side gate wiring lines 29. Note that the scanning signals are supplied from the first circuit portion 14A to the lower-layer side gate wiring line 25 and the upper-layer side gate wiring line 29 that overlap each other at the same timing, so that the lower-layer side gate wiring line 25 and the upper-layer side gate wiring line 29 are always at the same potential. Each of the source wiring lines 26 extends along the Y-axis direction (a second direction intersecting the first direction) to cross the display region AA, and intersects the lower-layer side gate wiring lines 25 and the upper-layer side gate wiring lines 29. The plurality of source wiring lines 26 are disposed at intervals in the X-axis direction. Therefore, the plurality of lower-layer side gate wiring lines 25 and the plurality of upper-layer side gate wiring lines 29, and the plurality of source wiring lines 26 form a lattice shape in plan view. The image signals output from the second circuit portion 14B are distributed to the source wiring lines 26.

As illustrated in FIG. 5, a TFT (switching element) 27 and a pixel electrode 28 are provided near each of intersections of both of the gate wiring lines 25 and 29 and the source wiring lines 26. The plurality of TFTs 27 and the plurality of pixel electrodes 28 are disposed regularly in the X-axis direction and the Y-axis direction. The TFT 27 includes at least a lower-layer side gate electrode 27A, a source region (a first conductivity-induced portion, a second conductivity-induced portion) 27B, a drain region 27C, a semiconductor portion (a first semiconductor portion) 27D, and an upper-layer side gate electrode (a first electrode) 27E. The lower-layer side gate electrode 27A is constituted by a part of the lower-layer side gate wiring line 25. The upper-layer side gate electrode 27E is constituted by a part of the upper-layer side gate wiring line 29. The source region 27B is connected to the source wiring line 26. The drain region 27C is connected to the pixel electrode 28. The source region 27B and the drain region 27C are in a relationship that the regions cross the respective gate wiring lines 25 and 29. The semiconductor portion 27D is connected to each of the source region 27B and the drain region 27C and overlaps a part of the lower-layer side gate electrode 27A and the entire region of the upper-layer side gate electrode 27E. As described above, the TFT 27 according to the present embodiment has a double gate structure in which the semiconductor portion 27D is sandwiched between the two upper-side layer and lower-side layer gate electrodes 27A and 27E. When such a TFT 27 is driven based on scanning signals supplied from the lower-layer side gate wiring line 25 and the upper-layer side gate wiring line 29 to the lower-layer side gate electrode 27A and the upper-layer side gate electrode 27E, two channel regions are generated on the upper layer side and the lower layer side in the semiconductor portion 27D. The image signal supplied from the source wiring line 26 to the source region 27B is supplied to the drain region 27C through the channel region of the semiconductor portion 27D, and the pixel electrode 28 is charged to a potential based on the image signal. As described above, the two channel regions are generated in the semiconductor portion 27D, thereby increasing a charge mobility. The pixel electrode 28 forms an elongated shape with a longitudinal direction matching the Y-axis direction.

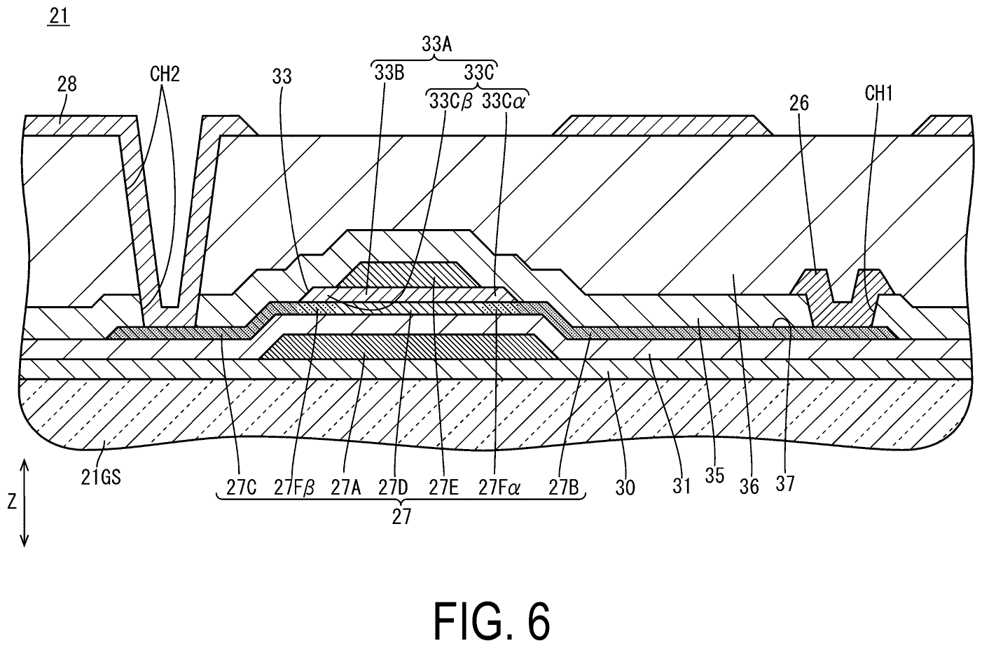

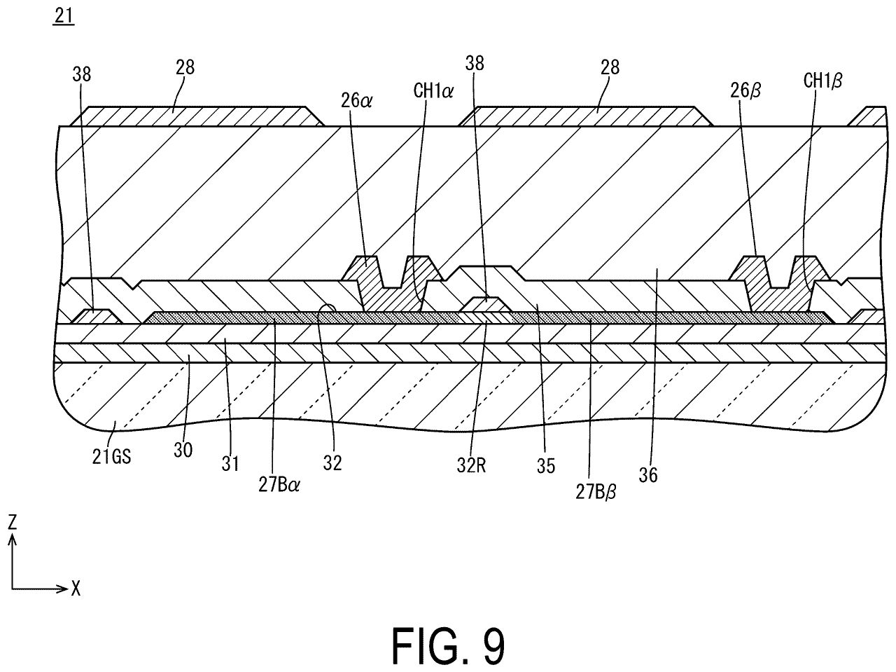

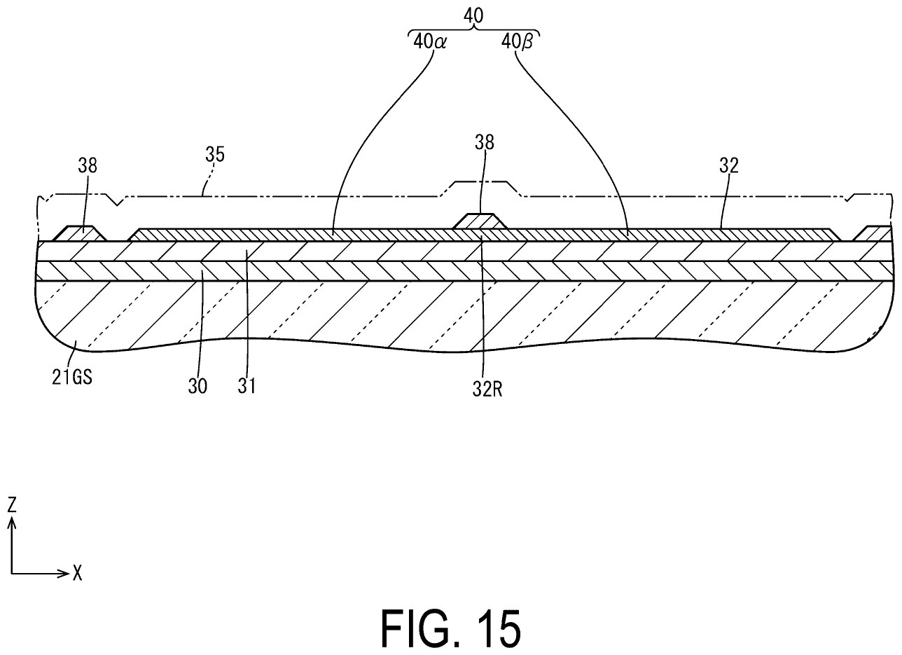

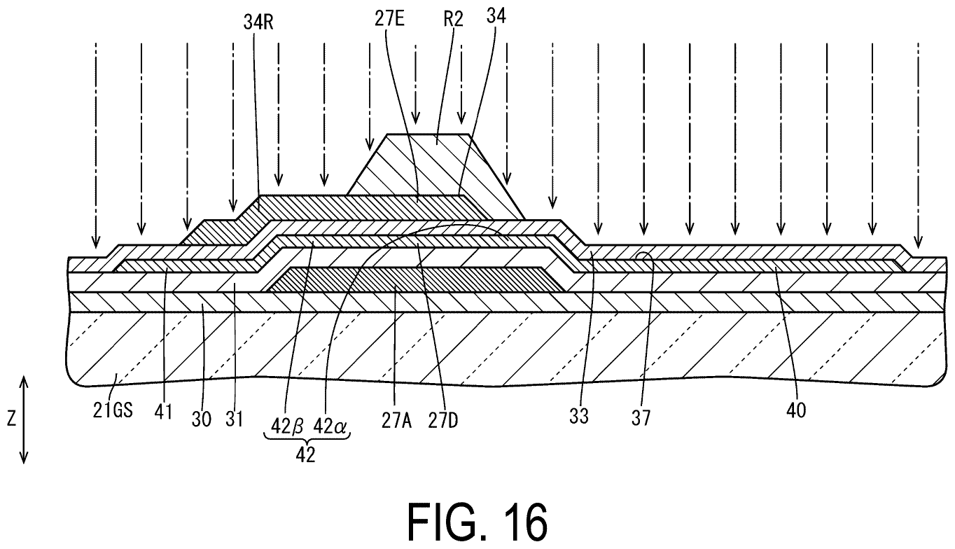

Subsequently, the various films layered on the glass substrate 21GS of the array substrate 21 will be described in detail with reference to FIG. 6. As illustrated in FIG. 6, at least a base coat film 30, a first metal film, a lower-layer side gate insulating film 31, a semiconductor film 32, an upper-layer side gate insulating film (first insulating film) 33, a second metal film (first conductive film) 34, a first interlayer insulating film (second insulating film) 35, a third metal film (second conductive film), a flattening film 36, and a first transparent electrode film are layered on the glass substrate 21GS of the array substrate 21 in this order from the lower layer side (glass substrate 21GS side) (see FIG. 9 and FIG. 15 regarding the semiconductor film 32 and see FIG. 16 regarding the second metal film 34). Note that an alignment film for aligning the liquid crystal molecules contained in the liquid crystal layer 22 is provided on the innermost face of the array substrate 21 facing the liquid crystal layer 22.

Each of the first metal film, the second metal film 34, and the third metal film is a single-layer film made of one type of metal material or a layered film or alloy made of different types of metal materials, and thus has electrical conductivity. As illustrated in FIG. 6, the first metal film constitutes the lower-layer side gate wiring line 25, the lower-layer side gate electrode 27A, and the like. The second metal film 34 constitutes the upper-layer side gate wiring line 29, the upper-layer side gate electrode 27E, and the like (see FIG. 16). The third metal film constitutes the source wiring line 26 and the like. The first transparent electrode film is made of a transparent electrode material such as Indium Tin Oxide (ITO), Indium Zinc Oxide (IZO), or the like. The first transparent electrode film constitutes the pixel electrode 28 and the like.

The semiconductor film 32 is made of an oxide semiconductor material (see FIG. 9 and FIG. 15). Specifically, the semiconductor film 32 is constituted by an oxide thin film containing indium (In), gallium (Ga), and zinc (Zn) being a kind of oxide semiconductor, for example. The oxide thin film containing indium (In), gallium (Ga), and zinc (Zn) is amorphous or crystalline. The oxide semiconductor material of the semiconductor film 32 has characteristics of higher resistance value in a state in which no voltage is applied (off state) than that of the silicon semiconductor material. Additionally, the oxide semiconductor material of the semiconductor film 32 has a higher electron mobility than that of an amorphous silicon semiconductor material.

As illustrated in FIG. 6, the array substrate 21 according to the present embodiment includes a semiconductor pattern portion 37 formed by patterning the semiconductor film 32. The semiconductor pattern portion 37 constitutes the source region 27B, the drain region 27C, the semiconductor portion 27D, and the like of the TFT 27. The semiconductor pattern portion 37 is partially made conductive (to have a low resistance). A portion of the semiconductor pattern portion 37 not made conductive (non-conductivity-induced portion, non-resistance-reduced portion) constitutes the semiconductor portion 27D and the like. Portions made conductive (conductivity-induced portions, resistance-reduced portions) of the semiconductor pattern portion 37 constitute the source region 27B, the drain region 27C, and the like. Note that, in the cross-sectional view of FIG. 6 and the like, a portion made conductive of the semiconductor pattern portion 37 is illustrated with shading. The non-conductivity-induced portion of the semiconductor pattern portion 37 is capable of charge movement only under specific conditions (when a scanning signal is supplied to each of the gate electrodes 27A and 27E). That is, the non-conductivity-induced portion functions as a channel region under the specific conditions. The non-conductivity-induced portion of the semiconductor pattern portion 37 has a sheet resistance of, for example, about 10⁶Ω/□ to 10⁷Ω/□. On the other hand, the non-conductivity-induced portion of the semiconductor pattern portion 37 functions as a conductor because charges can always move. The conductivity-induced portion of the semiconductor pattern portion 37 has a sheet resistance of, for example, about 10³Ω/□. That is, the conductivity-induced portion of the semiconductor pattern portion 37 has a lower resistivity of about 1/1000 to 1/10000 than that of the non-conductivity-induced portion.

Each of the base coat film 30, the lower-layer side gate insulating film 31, the upper-layer side gate insulating film 33, and the first interlayer insulating film 35 is made of an inorganic material (inorganic resin material) such as silicon oxide (SiO₂), or silicon nitride (SiNₓ). The base coat film 30 is directly layered on the glass substrate 21GS and positioned on the lower layer side of the first metal film. The lower-layer side gate insulating film 31 is positioned on the upper layer side of the first metal film and on the lower layer side of the semiconductor film 32. The lower-layer side gate insulating film 31 keeps the lower-layer side gate electrode 27A and the semiconductor portion 27D insulated from each other. The upper-layer side gate insulating film 33 is positioned on the upper-layer side of the semiconductor film 32 and on the lower layer side of the second metal film 34. The upper-layer side gate insulating film 33 keeps the semiconductor portion 27D and the upper-layer side gate electrode 27E insulated from each other. The first interlayer insulating film 35 is positioned on the upper layer side of the second metal film 34 and on the lower layer side of the third metal film. The first interlayer insulating film 35 keeps the upper-layer side gate electrode 27E and the source wiring line 26 insulated from each other. In the present embodiment, the first interlayer insulating film 35 is made of SiO₂, SiNₓ or a layered film of SiO₂ and SiNₓ, and contains, for example, H₂ (hydrogen) or the like as a reducing agent. The reason why the first interlayer insulating film 35 contains H₂ is that a hydride gas such as SiH₄ (silane gas), TEOS (tetraethyl orthosilicate), or NH₃ is contained as a material to be used for film formation. The flattening film 36 is made of an organic material (organic resin material) such as PMMA (acrylic resin). The flattening film 36 made of the organic material has a larger film thickness than those of the base coat film 30, the lower-layer side gate insulating film 31, the upper-layer side gate insulating film 33, and the first interlayer insulating film 35 each of which is made of an inorganic material. Specifically, a film thickness of each of the base coat film 30, the lower-layer side gate insulating film 31, the upper-layer side gate insulating film 33, and the first interlayer insulating film 35 each of which is made of the inorganic material is, for example, from about several tens nm to about several hundreds nm, whereas a film thickness of the first flattening film 36 is, for example, from about 1 μm to about 3 μm. The flattening film 36 keeps the source wiring line 26 and the pixel electrode 28 insulated from each other.

Note that when a display mode of the liquid crystal panel 11 is, for example, a Fringe Field Switching (FFS) mode or the like, a second interlayer insulating film on the upper layer side of the first transparent electrode film and a second transparent electrode film on the upper layer side of the second interlayer insulating film are layered on the array substrate 21. In this case, one of the first transparent electrode film and the second transparent electrode film constitutes the pixel electrode 28, and the other constitutes a common electrode having a common potential. On the other hand, when the display mode of the liquid crystal panel 11 is, for example, a Vertical Alignment (VA) mode, a Twisted Nematic (TN) mode, or the like, a counter electrode is provided on the counter substrate 20.

Here, a configuration of the TFT 27 will be described in detail below. As illustrated in FIG. 5, the semiconductor pattern portion 37 constituting the source region 27B, the drain region 27C, the semiconductor portion 27D, and the like of the TFT 27 has an L shape as a whole, and includes a portion extending along the X-axis direction and a portion extending along the Y-axis direction. Most of the portion of the semiconductor pattern portion 37 extending along the X-axis direction overlaps the pixel electrode 28 adjacent, on the upper side in FIG. 5 in the Y-axis direction, to the pixel electrode 28 to be connected. One end portion of a portion of the semiconductor pattern portion 37 extending along the X-axis direction overlaps the source wiring line 26, and the other end portion thereof is disposed in the vicinity of a substantially center position of the overlapped pixel electrode 28 in the X-axis direction. One end portion of the portion of the semiconductor pattern portion 37 extending along the Y-axis direction is connected to the other end portion of the portion extending along the X-axis direction, and an intermediate portion extending up to the other end portion is disposed so as to cross both of the gate wiring lines 25 and 29. In the portion of the semiconductor pattern portion 37 extending along the Y-axis direction, a portion closer to the other end portion side relative to both of the gate wiring lines 25 and 29 overlaps the pixel electrode 28 to be connected. Of the semiconductor pattern portion 37, the entire region of the portion extending along the X-axis direction and a part of the portion extending along the Y-axis direction (a portion from one end portion up to the upper-layer side gate wiring line 29) constitute the source region 27B. A portion of the semiconductor pattern portion 37 overlapping the upper-layer side gate wiring line 29 constitutes the semiconductor portion 27D. A part of the portion of the semiconductor pattern portion 37 extending along the Y-axis direction (a portion from the other end portion up to the upper-layer side gate wiring line 29) constitutes the drain region 27C.

As illustrated in FIG. 6, a source contact hole CH1 for connecting the source region 27B included in the semiconductor pattern portion 37 and the source wiring line 26 to be connected is formed as an opening in the first interlayer insulating film 35 interposed between the source region 27B and the source wiring line 26 to be connected. The source contact hole CH1 is disposed at a position overlapping the source region 27B and the source wiring line 26 in the first interlayer insulating film 35. As illustrated in FIG. 6, a drain contact hole CH2 for connecting the drain region 27C included in the semiconductor pattern portion 37 and the pixel electrode 28 to be connected is formed as an opening in the first interlayer insulating film 35 and the flattening film 36 interposed between the drain region 27C and the pixel electrode 28 to be connected. The drain contact hole CH2 is disposed at a position overlapping the drain region 27C and the pixel electrode 28 in the first interlayer insulating film 35 and the flattening film 36.

As illustrated in FIG. 6, the upper-layer side gate electrode 27E of the TFT 27 is narrower in width than the lower-layer side gate electrode 27A. The lower-layer side gate electrode 27A is disposed such that both side edges thereof protrude to both sides in the Y-axis direction relative to both side edges of the upper-layer side gate electrode 27E. Note that the lower-layer side gate electrode 27A and the upper-layer side gate electrode 27E may be disposed such that the centers thereof in the width direction (Y-axis direction) coincide with each other, or may be disposed such that the centers thereof are shifted from each other. The lower-layer side gate insulating film 31 interposed between the first metal film constituting the lower-layer side gate electrode 27A and the semiconductor film 32 constituting the semiconductor portion 27D and the like is disposed substantially in a solid-like state. On the other hand, the upper-layer side gate insulating film 33 interposed between the second metal film constituting the upper-layer side gate electrode 27E and the semiconductor film 32 constituting the semiconductor portion 27D and the like is selectively provided at a position overlapping the lower-layer side gate wiring line 25 and the upper-layer side gate wiring line 29.

Specifically, as illustrated in FIG. 5 and FIG. 6, the upper-layer side gate insulating film 33 includes a linear insulating portion 33A extending along the X-axis direction and being parallel to the lower-layer side gate wiring line 25 and the upper-layer side gate wiring line 29. The linear insulating portion 33A may be disposed within a belt-shaped range wider than the upper-layer side gate wiring line 29 and narrower than the lower-layer side gate wiring line 25. A portion of the linear insulating portion 33A overlapping the upper-layer side gate electrode 27E is a first insulating portion (overlapping insulating portion) 33B. The first insulating portion 33B is a portion of the linear insulating portion 33A having the same width as that of the upper-layer side gate electrode 27E. Portions of the linear insulating portion 33A not overlapping the upper-layer side gate electrode 27E and being continuous with the first insulating portion 33B are non-overlapping insulating portions 33C. The non-overlapping insulating portions 33C are portions of the linear insulating portion 33A protruding relative to the upper-layer side gate electrode 27E toward both sides in the Y-axis direction. A pair of non-overlapping insulating portions 33C are provided so as to be continuous with both side edges of the first insulating portion 33B. A width dimension of the non-overlapping insulating portion 33C, that is, a dimension protruding from a side edge of the first insulating portion 33B is, for example, about 0.5 μm to 2 μm. Hereinafter, when the pair of non-overlapping insulating portions 33C are distinguished from each other, the non-overlapping insulating portion 33C on the right side (source region 27B side) in FIG. 6 is referred to as a “first non-overlapping insulating portion (second insulating portion, source-side non-overlapping insulating portion)” and is denoted by using the reference sign and an index “a”, and the non-overlapping insulating portion 33C on the left side (drain region 27C side) in FIG. 6 is referred to as a “second non-overlapping insulating portion (third insulating portion, drain-side non-overlapping insulating portion)” and is denoted by using the reference sign and an index “β”. When the pair of non-overlapping insulating portions 33C are not distinguished from each other and are collectively referred to, no index is added to the reference sign.

As illustrated in FIG. 6, portions of the semiconductor pattern portion 37 that overlap the non-overlapping insulating portions 33C described above are high-resistance portions 27F having a higher resistance than those of the source region 27B and the drain region 27C. Note that in FIG. 6, the high-resistance portions 27F are illustrated in a shaded manner with a density lower than that of the source region 27B and the drain region 27C. The high-resistance portion 27F is in contact with the non-overlapping insulating portion 33C of the upper-layer side gate insulating film 33, and is not in direct contact with the first interlayer insulating film 35. On the other hand, the source region 27B and the drain region 27C of the semiconductor pattern portion 37 do not overlap the upper-layer side gate insulating film 33 (linear insulating portion 33A) and are in contact with the first interlayer insulating film 35 on the upper layer side. As such, since the source region 27B and the drain region 27C of the semiconductor film 32 made of the oxide semiconductor material are in contact with the first interlayer insulating film 35 containing a reducing agent, the reducing agent in the first interlayer insulating film 35 causes a reduction reaction in which oxygen is extracted. Thus, the source region 27B and the drain region 27C are made conductive. On the other hand, the high-resistance portions 27F are not in direct contact with the first interlayer insulating film 35, but are in contact with the source region 27B and the drain region 27C being continuous with the high-resistance portions 27F. Therefore, a reduction reaction in which oxygen is extracted by using the reducing agent through the source region 27B and the drain region 27C also occurs in the high-resistance portions 27F. At this time, a degree of reduction of the high-resistance portions 27F is lower than degrees of reduction of the source region 27B and the drain region 27C. As a result, the high-resistance portions 27F are made conductive to some extent, but have a resistance higher than those of the source region 27B and the drain region 27C. Here, when a channel region is generated in a first semiconductor portion 27Dα along with driving the TFT 27, an image signal supplied to the source region 27B is transmitted by the channel region of the semiconductor portion 27D through one high-resistance portion 27F. Then, the image signal is transmitted from the channel region of the semiconductor portion 27D to the drain region 27C through the other high-resistance portion 27F. As described above, since the high-resistance portion 27Fα is interposed between the source region 27Bα and the channel region of the semiconductor portion 27Dα and between the drain region 27C and the channel region of the semiconductor portion 27Dα, the occurrence of hot carrier injection is suitably suppressed.

As described above, although the high-resistance portions 27F are parts of the conductivity-induced portion in the semiconductor pattern portion 37, conductivity induction of the high-resistance portions 27F are suppressed so that the high-resistance portions 27F have a higher sheet resistance than those of the source region 27B and the drain region 27C. A pair of the high-resistance portions 27F are provided so as to protrude from both end portions of the semiconductor portion 27D in the Y-axis direction toward both sides in the Y-axis direction. A width dimension of the high-resistance portion 27F, that is, a dimension of the high-resistance portion 27F protruding from the end portion of the semiconductor portion 27D in the Y-axis direction is substantially the same as a width dimension of the non-overlapping insulating portion 33C, and is, for example, about 0.5 μm to 2 μm. One high-resistance portion 27F of the pair of high-resistance portions 27F is continuous with the source region 27B, and the other high-resistance portion 27F is continuous with the drain region 27C. In the following description, when the pair of high-resistance portions 27F are distinguished from each other, one high-resistance portion 27F continuous with the source region 27B is referred to as a “first high-resistance portion (source-side high-resistance portion)” and is denoted by using the reference sign and an index “α”, and the other high-resistance portion 27F continuous with the drain region 27C is referred to as a “second high-resistance portion (drain-side high-resistance portion)” and is denoted by using the reference sign and an index “β”. When the pair of high-resistance portions 27F are not distinguished from each other and are collectively referred to, no index is added to the reference sign. Thus, the semiconductor portion 27D is indirectly connected to the source region 27B and the drain region 27C with the pair of high-resistance portions 27F individually interposed therebetween.

Hereinafter, the configuration of the array substrate 21 illustrated in FIG. 5 is distinguished as follows. FIG. 5 illustrates, as an example, three TFTs 27 and three source wiring lines 26 spaced apart from each other in the X-axis direction, and the TFT 27 and the source wiring line 26 that are positioned at the central portion are respectively referred to as a “first TFT” and a “first source wiring line” each of which has the reference sign and an index “α”, and the TFT 27 and the source wiring line 26 that are positioned on the right side are referred to as a “second TFT” and a “second source wiring line” each of which has the reference sign and an index “β”. The lower-layer side gate electrode 27A, the source region 27B, the drain region 27C, the semiconductor portion 27D, and the upper-layer side gate electrode 27E that constitute the first TFT 27α are respectively referred to as a “first lower-layer side gate electrode”, a “first source region (first conductivity-induced portion)”, a “first drain region”, a “first semiconductor portion”, and a “first upper-layer side gate electrode” each of which has the reference sign and an index “α”. The lower-layer side gate electrode 27A, the source region 27B, the drain region 27C, the semiconductor portion 27D, and the upper-layer side gate electrode 27E that constitute the second TFT 27β are respectively referred to as a “second lower-layer side gate electrode”, a “second source region (second conductivity-induced portion)”, a “second drain region”, a “second semiconductor portion”, and a “second upper-layer side gate electrode” each of which has the reference sign and an index “β”. In addition, the source contact hole CH1 and the drain contact hole CH2 that are provided in the first TFT 27α are respectively referred to as a “first source contact hole (first contact hole)” and a “first drain contact hole” each of which has the reference sign and an index “α”, and the source contact hole CH1 and the drain contact hole CH2 that are provided in the second TFT 27β are respectively referred to as a “second source contact hole (second contact hole)” and a “second drain contact hole” each of which has the reference sign and an index “β”. Note that when the above-described configurations are collectively referred to without being distinguished from each other, no index is added to the reference sign of each configuration.

Further, in FIG. 5, three lower-layer side gate wiring lines 25, three upper-layer side gate wiring lines 29, and three linear insulating portions 33A that are spaced apart from each other in the Y-axis direction are illustrated. Among these, the lower-layer side gate wiring line 25, the upper-layer side gate wiring line 29, and the linear insulating portion 33A that are positioned at the central portion are respectively referred to as a “first lower-layer side gate wiring line, a first upper-layer side gate wiring line (first wiring line), and a first linear insulating portion” each of which has the reference sign and an index “α”, and the lower-layer side gate wiring line 25, the upper-layer side gate wiring line 29, and the linear insulating portion 33A, which are on the upper side, are respectively referred to as a “second lower-layer side gate wiring line, a second upper-layer side gate wiring line (second wiring line), and a second linear insulating portion” each of which has the reference sign and an index “β”. Note that when the above-described configurations are collectively referred to without being distinguished from each other, no index is added to the reference sign of each configuration.

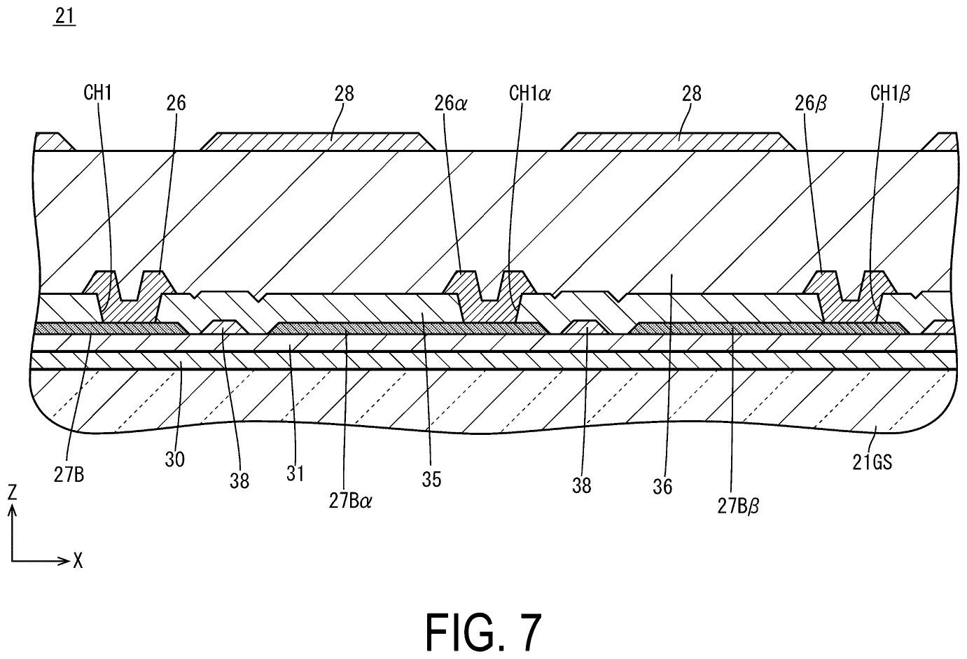

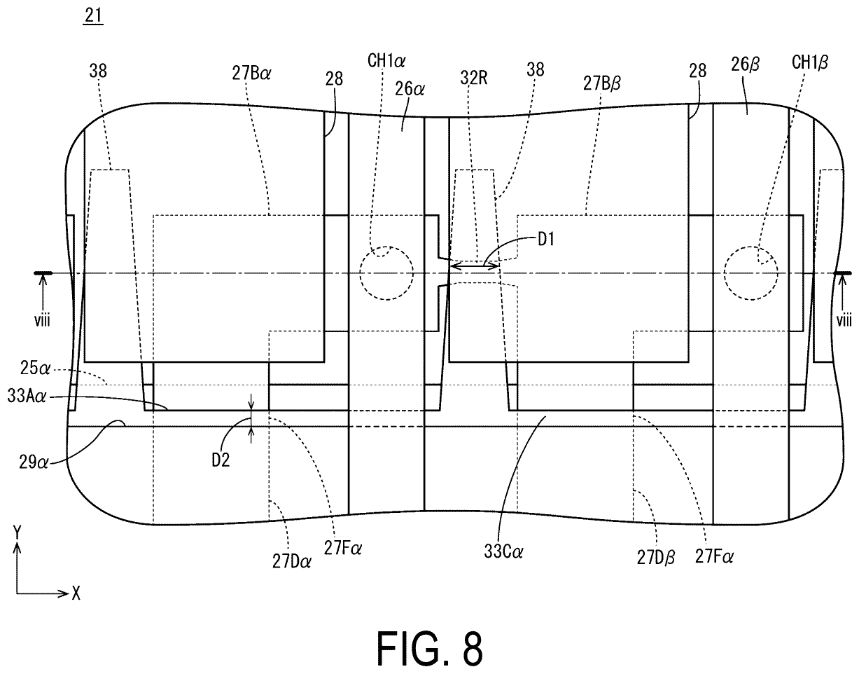

Now, as illustrated in FIG. 5 and FIG. 7, the array substrate 21 according to the present embodiment is provided with a source intervening portion (intervening portion, first intervening portion) 38 disposed between the first source region 27Bα and the second source region 27Bβ. The first source region 27Bα and the second source region 27Bβ are spaced apart from each other in the X-axis direction, and the source intervening portion 38 is disposed in the spaced region. Specifically, an end portion of the first source region 27Bα connected to the first source wiring line 26α (a portion overlapping the first source contact hole CH1α) and a bent portion of the second source region 27Bβ are spaced apart from each other by an interval of about several μm. Then, the source intervening portion 38 is constituted by a part (a portion other than the first insulating portion 33B) of the upper-layer side gate insulating film 33. Here, in the manufacturing process of the array substrate 21, when the semiconductor film 32 is patterned, as illustrated in FIG. 8 and FIG. 9, there is a possibility that a film residue is generated at the semiconductor film 32. When the film residue is generated, the first source region 27Bα and the second source region 27Bβ may be mechanically continuous with each other by a film residue portion 32R of the semiconductor film 32. Even in this case, since the source intervening portion 38 constituted by a part of the upper-layer side gate insulating film 33 is disposed between the first source region 27Bα and the second source region 27Bβ, the source intervening portion 38 overlaps the film residue portion 32R mechanically continuous with the first source region 27Bα and the second source region 27Bβ. Therefore, the film residue portion 32R of the semiconductor film 32 is masked from the first interlayer insulating film 35 by the source intervening portion 38 that overlaps the film residue portion 32R, so that the film residue portion 32R can be prevented from being made conductive. In other words, since the source intervening portion 38 is interposed between the film residue portion 32R of the semiconductor film 32 and the first interlayer insulating film 35, the film residue portion 32R is prevented from being in contact with the first interlayer insulating film 35, so that the film residue portion 32R is prevented from being reduced by the reducing agent of the first interlayer insulating film 35. As a result, the first source region 27Bα and the second source region 27Bβ are maintained in an electrically non-connected state with high reliability even when the film residue is generated at the semiconductor film 32. Therefore, the first source wiring line 26α connected to the first source region 27Bα through the first source contact hole CH1α of the first interlayer insulating film 35 and the second source wiring line 26β connected to the second source region 27Bβ through the second source contact hole CH1β of the first interlayer insulating film 35 are less likely to be short-circuited. Accordingly, a linear display defect caused by a short circuit between the first source wiring line 26α and the second source wiring line 26β is less likely to be visually recognized.

As illustrated in FIG. 8, a dimension (width dimension) of the source intervening portion 38 in the X-axis direction is smaller than an interval between the first source region 27Bα and the second source region 27Bβ in the X-axis direction. The dimension of the source intervening portion 38 in the X-axis direction is a distance D1 from an end portion of the source intervening portion 38 on the first source region 27Bα side (left side in FIG. 8) to an end portion thereof on the second source region 27Bβ side (right side in FIG. 8). However, the dimension of the source intervening portion 38 in the X-axis direction is larger than the dimension (width dimension) of the first high-resistance portion 27Fα in the Y-axis direction. The dimension of the first high-resistance portion 27Fα in the Y-axis direction is a distance D2 from an end portion of the first high-resistance portion 27Fα on the first semiconductor portion 27Dα side (lower side in FIG. 8) to an end portion of the first high-resistance portion 27Fα on the first source region 27Bα side (upper side in FIG. 8). When the film residue portion 32R mechanically continuous with the first source region 27Bα and the second source region 27Bβ is generated at the semiconductor film 32, a portion of the film residue portion 32R overlapping the end portion of the source intervening portion 38 on the first source region 27Bα side and a portion of the film residue portion 32R overlapping the end portion of the source intervening portion 38 on the second source region 27Bβ side may be made conductive. Even in this case, since the distance D1 from the end portion of the source intervening portion 38 on the first source region 27Bα side to the end portion of the source intervening portion 38 on the second source region 27Bβ side is larger than the distance D2 from the end portion of the first high-resistance portion 27Fα on the first semiconductor portion 27Dα side to the end portion of the first high-resistance portion 27Fα on the first source region 27Bα side, a case where the entire region of the film residue portion 32R of the semiconductor film 32 overlapping the source intervening portion 38 is made conductive is less likely to occur. As a result, the first source region 27Bα and the second source region 27Bβ are more reliably maintained in the electrically non-connected state.

As illustrated in FIG. 8, the source intervening portion 38 is configured to be continuous with the linear insulating portion 33A. Specifically, the source intervening portion 38 is provided so as to extend along the Y-axis direction from a portion, being adjacent to the intersection with the source wiring line 26, of the linear insulating portion 33A extending along the X-axis direction. The source intervening portion 38 has a tapered planar shape, and a width dimension (dimension in the X-axis direction) thereof decreases toward the extended end side. The source intervening portion 38 is configured such that the extended tip end portion thereof reaches a position beyond the first source region 27Bα and the second source region 27Bβ. That is, the dimension of the source intervening portion 38 in the Y-axis direction is larger than dimensions of the first source region 27Bα and the second source region 27Bβ in the Y-axis direction. With this configuration, the first source region 27Bα and the second source region 27Bβ are partitioned by the source intervening portion 38 over the entire length in the Y-axis direction. Therefore, the first source region 27Bα and the second source region 27Bβ are more reliably kept in an electrically non-connected state by the source intervening portion 38 over the entire length including a portion near the linear insulating portion 33A.

As illustrated in FIG. 5 and FIG. 7, the array substrate 21 is provided with a drain intervening portion (intervening portion, second intervening portion) 39 disposed between the first drain region 27Cα and the second drain region 27Cβ. The first drain region 27Cα and the second drain region 27Cβ are spaced apart from each other by about several μm in the X-axis direction, and the drain intervening portion 39 is disposed in the spaced region. Then, the drain intervening portion 39 is constituted by a part (a portion different from the first insulating portion 33B) of the upper-layer side gate insulating film 33. Here, when the semiconductor film 32 is patterned in the manufacturing process of the array substrate 21, there is a possibility that a film residue is generated at the semiconductor film 32 (see FIG. 8 and FIG. 9). When the film residue is generated, the first drain region 27Cα and the second drain region 27Cβ may be mechanically continuous with each other by the film residue portion 32R of the semiconductor film 32. Even in this case, since the drain intervening portion 39 constituted by a part of the upper-layer side gate insulating film 33 is disposed between the first drain region 27Cα and the second drain region 27Cβ, the drain intervening portion 39 overlaps the film residue portion 32R mechanically continuous with the first drain region 27Cα and the second drain region 27Cβ. Therefore, the film residue portion 32R of the semiconductor film 32 is masked from the first interlayer insulating film 35 by the drain intervening portion 39 overlapping the film residue portion 32R, so that the film residue portion 32R is prevented from being made conductive. In other words, the drain intervening portion 39 is interposed between the film residue portion 32R of the semiconductor film 32 and the first interlayer insulating film 35 to prevent the film residue portion 32R from being in contact with the first interlayer insulating film 35, thereby preventing the film residue portion 32R from being reduced by the reducing agent of the first interlayer insulating film 35. As a result, the first drain region 27Cα and the second drain region 27Cβ are maintained in an electrically non-connected state with high reliability even when a film residue is generated at the semiconductor film 32. Therefore, the pixel electrode 28 connected to the first drain region 27Cα through the first drain contact hole CH2α of the first interlayer insulating film 35 and the flattening film 36, and the pixel electrode 28 connected to the second drain region 27Cβ through the second drain contact hole CH2β of the first interlayer insulating film 35 and the flattening film 36 are less likely to be short-circuited.

Accordingly, a dot-like display defect caused by a short circuit between two pixel electrodes 28 adjacent to each other in the X-axis direction is less likely to be visually recognized.

As illustrated in FIG. 5, a dimension (width dimension) of the drain intervening portion 39 in the X-axis direction is smaller than an interval between the first drain region 27Cα and the second drain region 27Cβ in the X-axis direction. The dimension of the drain intervening portion 39 in the X-axis direction is a distance from an end portion of the drain intervening portion 39 on the first drain region 27Cα side (left side in FIG. 5) to an end portion of the drain intervening portion 39 on the second drain region 27Cβ side (right side in FIG. 5). However, the dimension of the drain intervening portion 39 in the X-axis direction is larger than a dimension (width dimension) of the second high-resistance portion 27Fβ in the Y-axis direction. The dimension of the second high-resistance portion 27Fβ in the Y-axis direction is a distance from an end portion of the second high-resistance portion 27Fβ on the first semiconductor portion 27Dα side (upper side in FIG. 5) to an end portion of the second high-resistance portion 27Fβ on the first drain region 27Cα side (lower side in FIG. 5). When the film residue portion 32R mechanically continuous with the first drain region 27Cα and the second drain region 27Cβ is generated at the semiconductor film 32, a portion of the film residue portion 32R overlapping an end portion of the drain intervening portion 39 on the first drain region 27Cα side and a portion of the film residue portion 32R overlapping an end portion of the drain intervening portion 39 on the second drain region 27Cβ side may be made conductive. Even in this case, since the distance from the end portion of the drain intervening portion 39 on the first drain region 27Cα side to the end portion of the drain intervening portion 39 on the second drain region 27Cβ side is larger than the distance from the end portion of the second high-resistance portion 27Fβ on the first semiconductor portion 27Dα side to the end portion of the second high-resistance portion 27Fβ on the first drain region 27Cα side, the entire region of the film residue portion 32R of the semiconductor film 32 overlapping the drain intervening portion 39 is less likely to become conductive. Thus, the first drain region 27Cα and the second drain region 27Cβ are more reliably maintained in the electrically non-connected state.

As illustrated in FIG. 5, the drain intervening portion 39 is configured to be continuous with the linear insulating portion 33A. Specifically, the drain intervening portion 39 is provided so as to extend along the Y-axis direction from a portion, being adjacent to an intersection with the source wiring line 26, of the linear insulating portion 33A extending along the X-axis direction, toward a side opposite to the source intervening portion 38 side. That is, the drain intervening portion 39 is disposed substantially at the same position as the source intervening portion 38 in the X-axis direction. The drain intervening portion 39 has a tapered planar shape and has a width dimension (dimension in the X-axis direction) thereof decreases toward the extended end side. Then, the drain intervening portion 39 is configured such that the extended tip end portion reaches a position beyond the first drain region 27Cα and the second drain region 27Cβ. That is, a dimension of the drain intervening portion 39 in the Y-axis direction is larger than a dimension of each of the first drain region 27Cα and the second drain region 27Cβ in the Y-axis direction. With this configuration, the first drain region 27Cα and the second drain region 27Cβ are partitioned by the drain intervening portion 39 over the entire length in the Y-axis direction. Therefore, the first drain region 27Cα and the second drain region 27Cβ are reliably kept in an electrically non-connected state by the drain intervening portion 39 over the entire length including a portion near the linear insulating portion 33A.

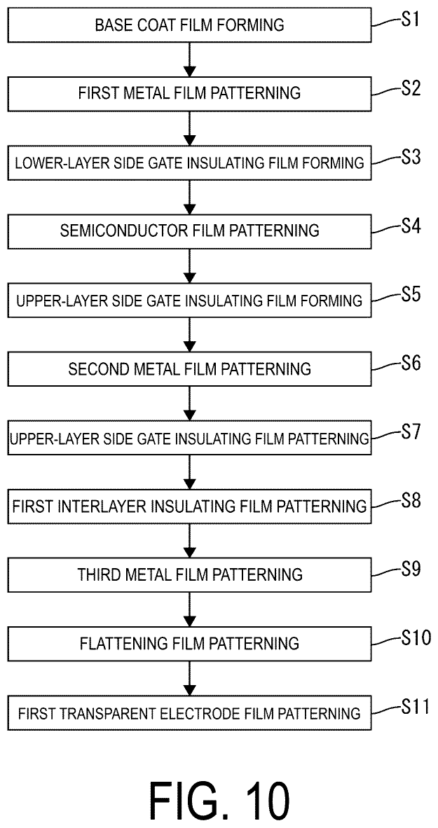

The present embodiment has the structure described above, and next, a method for manufacturing the array substrate 21 will be described. As illustrated in FIG. 10, the method for manufacturing the array substrate 21 includes at least base coat film forming S1 of forming the base coat film 30, first metal film patterning S2 of forming and patterning the first metal film, lower-layer side gate insulating film forming S3 of forming the lower-layer side gate insulating film 31, semiconductor film patterning S4 of forming and patterning the semiconductor film 32, upper-layer side gate insulating film forming S5 of forming the upper-layer side gate insulating film 33, second metal film patterning S6 of forming and patterning the second metal film 34, upper-layer side gate insulating film patterning S7 of patterning the upper-layer side gate insulating film 33, first interlayer insulating film patterning S8 of forming and patterning the first interlayer insulating film 35, third metal film patterning S9 of forming and patterning the third metal film, flattening film patterning S10 of forming and patterning the flattening film 36, and first transparent electrode film patterning S11 of forming and patterning the first transparent electrode film. Hereinafter, the second metal film patterning S6, the upper-layer side gate insulating film patterning S7, and the first interlayer insulating film patterning S8 among the above-described processes will be described in detail.

The term “patterning” described above means a process of a film based on a general photolithography method. Specifically, the process, that is, the patterning of a film to be processed is performed by performing the film formation of a photoresist film on the film to be processed, exposing the photoresist film with an exposure device through a photomask having a predetermined opening pattern, and then developing the photoresist film, and performing etching through the developed photoresist film.

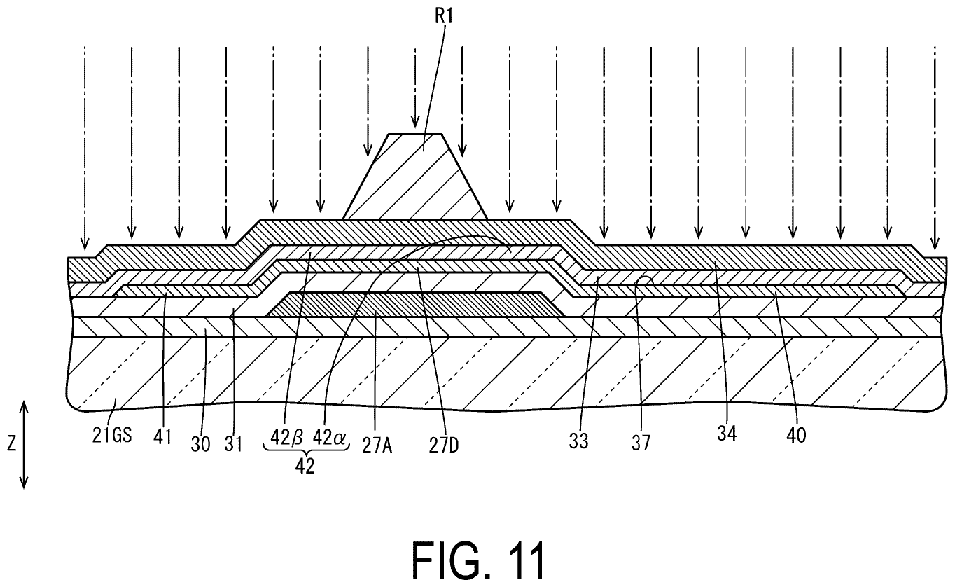

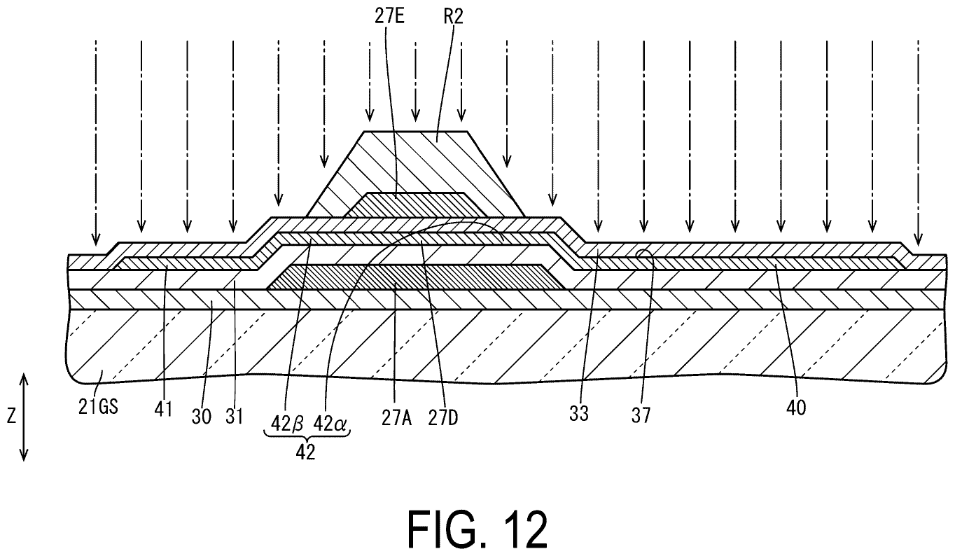

After the semiconductor film 32 is patterned through the semiconductor film patterning S4, the upper-layer side gate insulating film forming S5 and the second metal film patterning S6 are successively performed. Note that when the semiconductor film patterning S4 is performed, the entire region of the semiconductor pattern portion 37 of the patterned semiconductor film 32 is not made conductive (see FIG. 11). When the upper-layer side gate insulating film forming S5 and the second metal film patterning S6 are successively performed, as illustrated in FIG. 11, the upper-layer side gate insulating film 33 and the second metal film 34 are successively continuously formed on the upper layer side of the semiconductor film 32. In the second metal film patterning S6, a first photoresist film R1 made of a photosensitive material is formed on the upper layer side of the second metal film 34, and the first photoresist film R1 is exposed through a photomask having a predetermined opening pattern. When the exposed first photoresist film R1 is developed, a portion (see FIG. 12) of the first photoresist film R1 overlapping a portion where the upper-layer side gate electrode 27E is to be formed remains. When etching is performed through the remaining first photoresist film R1, the second metal film 34 is patterned, and the portion overlapping the first photoresist film R1 is selectively left to become the upper-layer side gate electrode 27E.

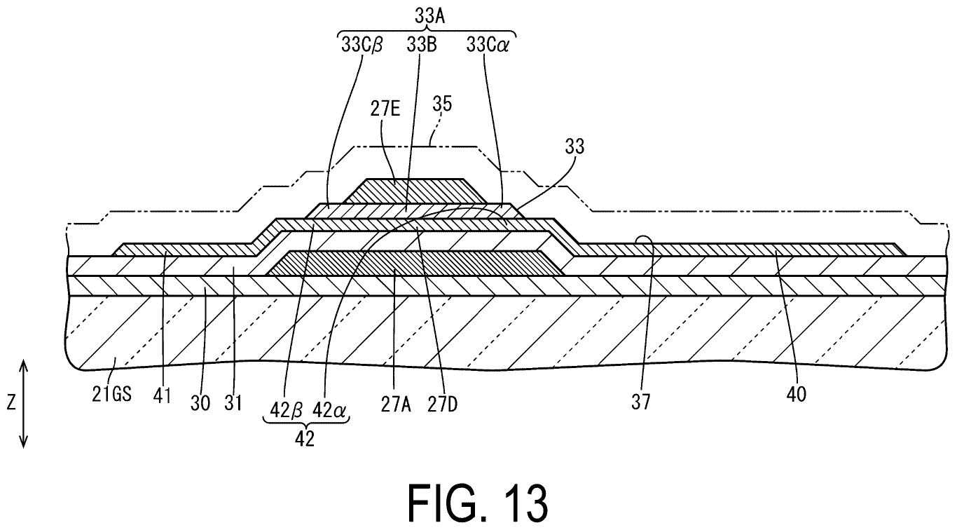

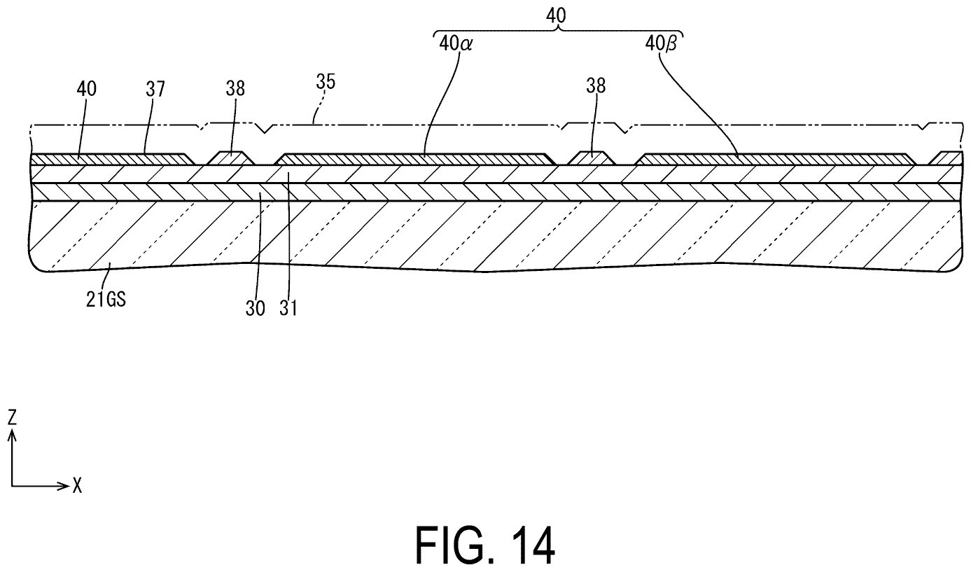

Thereafter, when the upper-layer side gate insulating film patterning S7 is performed, a second photoresist film R2 made of a photosensitive material is formed on the upper layer side of the upper-layer side gate insulating film 33, and the second photoresist film R2 is exposed through a photomask having a predetermined opening pattern. When the exposed second photoresist film R2 is developed, the second photoresist film R2 remains in a portion overlapping a portion where the linear insulating portion 33A is to be formed (see FIG. 13), a portion overlapping a portion where the source intervening portion 38 is to be formed (see FIG. 14), and a portion overlapping a portion where the drain intervening portion 39 is to be formed (see FIG. 5). When etching is performed through the remaining second photoresist film R2, the upper-layer side gate insulating film 33 is patterned, and as illustrated in FIG. 13 and FIG. 14, the portions overlapping the second photoresist film R2 are selectively left to become the linear insulating portion 33A, the source intervening portion 38, and the drain intervening portion 39 (see FIG. 5).

Here, as illustrated in FIG. 13 and FIG. 14, the semiconductor pattern portion 37, of the semiconductor film 32, entirely not made conductive, includes the semiconductor portion 27D overlapping the upper-layer side gate electrode 27E and the first insulating portion 33B (including the first semiconductor portion 27Dα overlapping the first upper-layer side gate electrode 27Eα), a source non-conductivity-induced portion 40 and a drain non-conductivity-induced portion 41 not overlapping the linear insulating portion 33A (the first insulating portion 33B and the non-overlapping insulating portions 33C), and an intermediate non-conductivity-induced portion 42 overlapping the non-overlapping insulating portion 33C and positioned between the semiconductor portion 27D and the source non-conductivity-induced portion 40. The source non-conductivity-induced portion 40 is a portion that becomes the source region 27B by being made conductive. The drain non-conductivity-induced portion 41 is a portion that becomes the drain region 27C by being made conductive. The intermediate non-conductivity-induced portion 42 is a portion that becomes the high-resistance portion 27F by being made conductive.

Note that in the following description, when the source non-conductivity-induced portions 40 are distinguished from each other, the source non-conductivity-induced portion 40 that becomes the first source region 27Bα is referred to as a “first source non-conductivity-induced portion (first non-conductivity-induced portion)” and is denoted by using the reference sign and an index “α”, and the source non-conductivity-induced portion 40 that becomes the second source region 27Bβ is referred to as a “second source non-conductivity-induced portion (second non-conductivity-induced portion)” and is denoted by using the reference sign and an index “β”. When the source non-conductivity-induced portions 40 are not distinguished from each other and are collectively referred to, no index is added to the reference sign. As illustrated in FIG. 14, the first source non-conductivity-induced portion 40α and the second source non-conductivity-induced portion 40β are spaced apart from each other in the X-axis direction. Additionally, when the intermediate non-conductivity-induced portions 42 are distinguished from each other, the intermediate non-conductivity-induced portion 42 continuous with the source non-conductivity-induced portion 40 is referred to as a “first intermediate non-conductivity-induced portion (third non-conductivity-induced portion)” and is denoted by using the reference sign and an index “α”, and the intermediate non-conductivity-induced portion 42 continuous with the drain non-conductivity-induced portion 41 is referred to as a “second intermediate non-conductivity-induced portion” and is denoted by using the reference sign and an index “β”. When the intermediate non-conductivity-induced portions 42 are not distinguished from each other and are collectively referred to, no index is added to the reference sign.

When the first interlayer insulating film patterning S8 is performed after the upper-layer side gate insulating film patterning S7 is performed, the first interlayer insulating film 35 is formed as indicated by a two-dot chain line in each of FIG. 13 and FIG. 14. The formed first interlayer insulating film 35 is in contact with the source non-conductivity-induced portion 40 and the drain non-conductivity-induced portion 41 of the semiconductor pattern portion 37, but is not in contact with the intermediate non-conductivity-induced portion 42. Since the first interlayer insulating film 35 contains the reducing agent, a reduction reaction in which oxygen is extracted by the reducing agent of the first interlayer insulating film 35 occurs in the source non-conductivity-induced portion 40 and the drain non-conductivity-induced portion 41 that are in contact with the first interlayer insulating film 35. In this way, the source non-conductivity-induced portion 40 and the drain non-conductivity-induced portion 41 become the source region 27B and the drain region 27C by being made conductive (see FIG. 6). On the other hand, since the first intermediate non-conductivity-induced portion 42α that is not in direct contact with the first interlayer insulating film 35 is adjacent to the source non-conductivity-induced portion 40, the reduction reaction in which oxygen is extracted by the reducing agent through the source non-conductivity-induced portion 40 also occurs in the first intermediate non-conductivity-induced portion 42α. Similarly, since the second intermediate non-conductivity-induced portion 42β is adjacent to the drain non-conductivity-induced portion 41, the reduction reaction in which oxygen is extracted by the reducing agent through the drain non-conductivity-induced portion 41 also occurs in the second intermediate non-conductivity-induced portion 42β. At this time, the degree of reduction of the intermediate non-conductivity-induced portion 42 is lower than the degrees of reduction of the source non-conductivity-induced portion 40 and the drain non-conductivity-induced portion 41. In this way, the intermediate non-conductivity-induced portion 42 becomes the high-resistance portion 27F having a resistance higher than those of the source region 27B and the drain region 27C by being made conductive (see FIG. 6).

Meanwhile, when a film residue is generated at the semiconductor pattern portion 37 of the semiconductor film 32 patterned through the semiconductor film patterning S4, the first source non-conductivity-induced portion 40α and the second source non-conductivity-induced portion 40β may be mechanically continuous with each other by the film residue portion 32R as illustrated in FIG. 15. Even in this case, since the source intervening portion 38 of the upper-layer side gate insulating film 33 patterned through the upper-layer side gate insulating film patterning S7 is disposed between the first source non-conductivity-induced portion 40α and the second source non-conductivity-induced portion 40β, the source intervening portion 38 is layered (disposed to be overlapped) on the upper layer side of the film residue portion 32R. Therefore, even when the first interlayer insulating film 35 containing the reducing agent is formed in the first interlayer insulating film patterning S8, the source intervening portion 38 is interposed between the first interlayer insulating film 35 and the film residue portion 32R of the semiconductor film 32, so that the first interlayer insulating film 35 can be prevented from coming into contact with the film residue portion 32R. As a result, the film residue portion 32R of the semiconductor film 32 is not reduced and is prevented from being made conductive. As described above, even when a film residue is generated at the semiconductor film 32, the first source region 27Bα and the second source region 27Bβ are maintained in the electrically non-connected state with higher reliability.

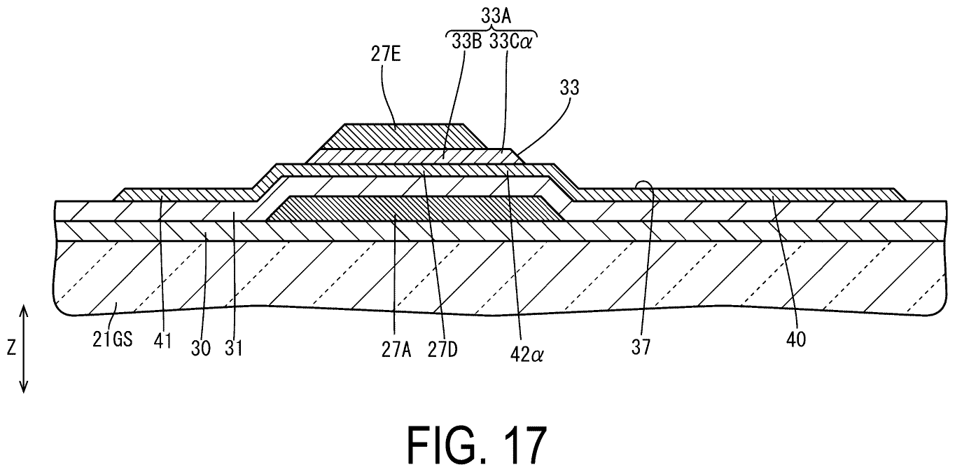

Here, when a film residue is generated at the second metal film 34 patterned through the second metal film patterning S6, as illustrated in FIG. 16, for example, a film residue portion 34R may remain over a range being continuous with the upper-layer side gate electrode 27E and overlapping the drain non-conductivity-induced portion 41. Even in this case, since the second metal film patterning S6 is performed and then the upper-layer side gate insulating film patterning S7 is performed in the present embodiment, the following actions and effects can be obtained. That is, when the upper-layer side gate insulating film patterning S7 is performed after the second metal film patterning S6 and the second photoresist film R2 is developed, the film residue portion 34R of the second metal film 34 is not covered with the remaining second photoresist film R2 as illustrated in FIG. 17. Therefore, when the upper-layer side gate insulating film 33 is etched through the second photoresist film R2, the film residue portion 34R of the second metal film 34 is also etched. In this way, since the film residue portion 34R of the second metal film 34 can be removed as illustrated in FIG. 17, it is possible to avoid a situation where the upper-layer side gate electrode 27E is short-circuited with the pixel electrode 28 through the film residue portion 34R. Note that even when the film residue portion 34R of the second metal film 34 is continuous with the upper-layer side gate electrode 27E and remains over a range overlapping the source non-conductivity-induced portion 40, the film residue portion 34R can be removed in a manner similar to that described above, thereby preventing the upper-layer side gate electrode 27E from being short-circuited with the source wiring line 26 through the film residue portion 34R.

As described above, the array substrate 21 according to the present embodiment includes the upper-layer side gate electrode (first electrode) 27E constituted by the second metal film (first conductive film) 34, the upper-layer side gate insulating film (first insulating film) 33 disposed on the lower layer side of the second metal film 34, the first source region (first conductivity-induced portion) 27Bα obtained by making the portion not overlapping the upper-layer side gate electrode 27E, of the semiconductor film 32 disposed on the lower layer side of the upper-layer side gate insulating film 33, conductive, the second source region (second conductivity-induced portion) 27Bβ obtained by making the portion of the semiconductor film 32 being other than the first source region 27Bα and not overlapping the upper-layer side gate electrode 27E conductive, the first semiconductor portion 27Dα constituted by the portion of the semiconductor film 32 overlapping the upper-layer side gate electrode 27E, and the source intervening portion (intervening portion) 38 constituted by a part of the upper-layer side gate insulating film 33 and disposed between the first source region 27Bα and the second source region 27Bβ.

The portions of the semiconductor film 32 not overlapping the upper-layer side gate electrode 27E are referred to as the first source region 27Bα and the second source region 27Bβ, whereas the portion of the semiconductor film 32 overlapping the upper-layer side gate electrode 27E is referred to as the first semiconductor portion 27Dα. Here, when a film residue is generated at the semiconductor film 32 in patterning the semiconductor film 32, the first source region 27Bα and the second source region 27Bβ may be mechanically continuous with each other by the film residue portion 32R. Even in this case, since the source intervening portion 38 constituted by a part of the upper-layer side gate insulating film 33 is disposed between the first source region 27Bα and the second source region 27Bβ, the source intervening portion 38 overlaps the film residue portion 32R mechanically continuous with the first source region 27Bα and the second source region 27Bβ. Therefore, the film residue portion 32R of the semiconductor film 32 is masked by the source intervening portion 38 overlapping therewith, so that the film residue portion 32R is prevented from being made conductive. As a result, the first source region 27Bα and the second source region 27Bβ are maintained in an electrically non-connected state with high reliability even when the film residue is generated at the semiconductor film 32.

Further, the upper-layer side gate insulating film 33 includes the first insulating portion 33B overlapping the upper-layer side gate electrode 27E and the first semiconductor portion 27Dα, and the source intervening portion 38 is constituted by a portion of the upper-layer side gate insulating film 33 different from the first insulating portion 33B. The upper-layer side gate electrode 27E and the first semiconductor portion 27Dα are kept insulated from each other by the first insulating portion 33B of the upper-layer side gate insulating film 33. The source intervening portion 38 constituted by the portion of the upper-layer side gate insulating film 33 different from the first insulating portion 33B is disposed between the first source region 27Bα and the second source region 27Bβ, thereby making it possible to prevent the film residue portion 32R of the semiconductor film 32 continuous with the first source region 27Bα and the second source region 27Bβ from being made conductive.

In addition, the semiconductor film 32 is made of the oxide semiconductor material, is disposed on the upper layer side of the second metal film 34, and includes the first interlayer insulating film (second insulating film) 35 containing the reducing agent. The first interlayer insulating film 35 is in contact with the first source region 27Bα and the second source region 27Bβ. The upper-layer side gate insulating film 33 includes the first non-overlapping insulating portion (second insulating portion) 33Cα being continuous with the first insulating portion 33B and not overlapping the upper-layer side gate electrode 27E and the first semiconductor portion 27Dα. The first high-resistance portion 27Fα is constituted by the portion of the semiconductor film 32 overlapping the first non-overlapping insulating portion 33Cα, is continuous with the first source region 27Bα, and has a resistance higher than that of the first source region 27Bα. The first source region 27Bα and the second source region 27Bβ, of the semiconductor film 32 made of the oxide semiconductor material, are reduced and made conductive by being in contact with the first interlayer insulating film 35 containing the reducing agent (for example, hydrogen or the like). The first non-overlapping insulating portion 33Cα of the upper-layer side gate insulating film 33 is continuous with the first insulating portion 33B without overlapping the upper-layer side gate electrode 27E and the first semiconductor portion 27Dα. Therefore, the first high-resistance portion 27Fα, which is the portion of the semiconductor film 32 overlapping the first non-overlapping insulating portion 33Cα, is not in direct contact with the first interlayer insulating film 35. However, since the first interlayer insulating film 35 is in contact with the first source region 27Bα continuous with the first high-resistance portion 27Fα, the first high-resistance portion 27Fα is also reduced, and as a result, the first high-resistance portion 27Fα is made conductive to some extent and has a resistance higher than that of the first source region 27Bα. Here, when a signal is supplied to the upper-layer side gate electrode 27E, a channel region is generated in the first semiconductor portion 27Dα, and thus, a signal supplied to the first source region 27Bα is transmitted by the channel region of the first semiconductor portion 27Dα through the first high-resistance portion 27Fα. Since the first high-resistance portion 27Fα is interposed between the first source region 27Bα and the channel region of the first semiconductor portion 27Dα, the occurrence of hot carrier injection is suitably suppressed.

Further, in the source intervening portion 38, the distance D1 from the end portion on the first source region 27Bα side to the end portion on the second source region 27Bβ side is larger than the distance D2 from the end portion on the first semiconductor portion 27Dα side to the end portion on the first source region 27Bα side, of the first high-resistance portion 27Fα. When the film residue portion 32R mechanically continuous with the first source region 27Bα and the second source region 27Bβ is generated at the semiconductor film 32, a portion of the film residue portion 32R overlapping the end portion of the source intervening portion 38 on the first source region 27Bα side and a portion of the film residue portion 32R overlapping the end portion of the source intervening portion 38 on the second source region 27Bβ side may be made conductive. Even in this case, since the distance D1 from the end portion of the source intervening portion 38 on the first source region 27B side to the end portion of the source intervening portion 38 on the second source region 27Bβ side is larger than the distance D2 from the end portion of the first high-resistance portion 27F on the first semiconductor portion 27Dα side to the end portion of the first high-resistance portion 27Fα on the first source region 27Bα side, a case where the entire region of the film residue portion 32R of the semiconductor film 32 overlapping the source intervening portion 38 is made conductive is less likely to occur. As a result, the first source region 27Bα and the second source region 27Bβ are more reliably maintained in the electrically non-connected state.

Further, the upper-layer side gate wiring line (first wiring line) 29α constituted by the second metal film 34, extending along the first direction, and including the upper-layer side gate electrode 27E, and the first linear insulating portion 33Aα constituted by the upper-layer side gate insulating film 33, extending along the first direction and overlapping the first upper-layer side gate wiring line 29α, and including the first insulating portion 33B are provided. The first source region 27Bα and the second source region 27Bβ intersect the first upper-layer side gate wiring line 29α and the first linear insulating portion 33Aα. The source intervening portion 38 is continuous with the first linear insulating portion 33Aα. The source intervening portion 38 continuous with the first linear insulating portion 33Aα is disposed between the first source region 27Bα and the second source region 27Bβ that intersect the first upper-layer side gate wiring line 29α and the first linear insulating portion 33Aα. As a result, portions of the first source region 27Bα and the second source region 27Bβ in the vicinity of the first upper-layer side gate wiring line 29α and the first linear insulating portion 33Aα are also maintained in the electrically non-connected state by the source intervening portion 38 with high reliability.

Further, the first interlayer insulating film 35 disposed on the upper layer side of the second metal film 34, the first source wiring line (third wiring line) 26α constituted by the third metal film (second conductive film) disposed on the upper layer side of the first interlayer insulating film 35, and partially overlapping the first source region 27Bα, and the second source wiring line (fourth wiring line) 26β constituted by the portion of the third metal film other than the first source wiring line 26α and partially overlapping the second source region 27Bβ are provided. The first source contact hole (first contact hole) CH1α connecting the first source wiring line 26α and the first source region 27Bα is provided at a position overlapping both the first source wiring line 26α and the first source region 27Bα of the first interlayer insulating film 35. The second source contact hole (second contact hole) CH1β connecting the second source wiring line 26β and the second source region 27Bβ is provided at a position of the first interlayer insulating film 35 overlapping both the second source wiring line 26β and the second source region 27Bβ. Even when a film residue is generated at the semiconductor film 32, the source intervening portion 38 ensures that the first source region 27Bα and the second source region 27Bβ are maintained in an electrically non-connected state with high reliability. Therefore, the first source wiring line 26α connected to the first source region 27Bα through the first source contact hole CH1α of the first interlayer insulating film 35 and the second source wiring line 26β connected to the second source region 27Bβ through the second source contact hole CH1β of the first interlayer insulating film 35 are less likely to be short-circuited.

Further, the liquid crystal panel (display device) 11 according to the present embodiment includes the above-described array substrate 21 and the counter substrate 20 facing the array substrate 21. According to such a liquid crystal panel 11, since the occurrence of a short circuit between the first source region 27Bα and the second source region 27Bβ included in the array substrate 21 is suppressed, it is possible to maintain excellent display quality.

Further, the method for manufacturing the array substrate 21 according to the present embodiment includes forming the semiconductor film 32 made of the oxide semiconductor material, patterning the semiconductor film 32, and thus providing the first source non-conductivity-induced portion (first non-conductivity-induced portion) 40α, the second source non-conductivity-induced portion (second non-conductivity-induced portion) 40β spaced apart from the first source non-conductivity-induced portion 40α, and the first semiconductor portion 27Dα, forming the upper-layer side gate insulating film 33 on the upper layer side of the semiconductor film 32, forming the second metal film 34 on the upper layer side of the upper-layer side gate insulating film 33, patterning the second metal film 34, and thus providing the upper-layer side gate electrode 27E overlapping the first semiconductor portion 27Dα, patterning the upper-layer side gate insulating film 33, and thus providing the first insulating portion 33B overlapping the upper-layer side gate electrode 27E and the first semiconductor portion 27Dα and the source intervening portion 38 disposed between the first source non-conductivity-induced portion 40α and the second source non-conductivity-induced portion 40β, and forming the first interlayer insulating film 35 including the reducing agent on the upper layer side of the second metal film 34, bringing the first interlayer insulating film 35 into contact with the first source non-conductivity-induced portion 40α and the second source non-conductivity-induced portion 40β, making the first source non-conductivity-induced portion 40α and the second source non-conductivity-induced portion 40β conductive, and thus changing the first source non-conductivity-induced portion 40α and the second source non-conductivity-induced portion 40β into the first source region 27Bα and the second source region 27Bβ, respectively.

When a film residue is generated at the semiconductor film 32 in the patterning of the semiconductor film 32, the first source non-conductivity-induced portion 40α and the second source non-conductivity-induced portion 40β may be mechanically continuous with each other by the film residue portion 32R. Even in this case, when the upper-layer side gate insulating film 33 is patterned, the first insulating portion 33B overlapping the upper-layer side gate electrode 27E and the first semiconductor portion 27Dα and the source intervening portion 38 disposed between the first source non-conductivity-induced portion 40α and the second source non-conductivity-induced portion 40β are provided, and among these, the source intervening portion 38 overlaps the film residue portion 32R of the semiconductor film 32. Therefore, even when the first interlayer insulating film 35 containing the reducing agent is formed on the upper layer side of the second metal film 34, and the first interlayer insulating film 35 is in contact with the first source non-conductivity-induced portion 40α and the second source non-conductivity-induced portion 40β, the first interlayer insulating film 35 can be prevented from being in contact with the film residue portion 32R of the semiconductor film 32. Thus, the first source non-conductivity-induced portion 40α and the second source non-conductivity-induced portion 40β that are in contact with the first interlayer insulating film 35 are reduced and made conductive to become the first source region 27Bα and the second source region 27Bβ, while the film residue portion 32R of the semiconductor film 32 is not reduced and is prevented from being made conductive. As described above, even when the film residue is generated at the semiconductor film 32, the first source region 27Bα and the second source region 27Bβ are maintained in the electrically non-connected state with higher reliability.

Further, the first non-overlapping insulating portion 33Cα not overlapping the upper-layer side gate electrode 27E and the first semiconductor portion 27Dα and being continuous with the first insulating portion 33B is provided by patterning the upper-layer side gate insulating film 33, the first intermediate non-conductivity-induced portion (third non-conductivity-induced portion) 42α overlapping the first non-overlapping insulating portion 33Cα and being continuous with the first source non-conductivity-induced portion 40α is provided by patterning the semiconductor film 32, and the first intermediate non-conductivity-induced portion 42α becomes the first high-resistance portion 27Fα having a resistance higher than that of the first source region 27Bα by forming the first interlayer insulating film 35. The first non-overlapping insulating portion 33Cα provided by patterning the upper-layer side gate insulating film 33 is continuous with the first insulating portion 33B without overlapping the upper-layer side gate electrode 27E and the first semiconductor portion 27Dα. The first intermediate non-conductivity-induced portion 42α provided by patterning the semiconductor film 32 overlaps the first non-overlapping insulating portion 33Cα and is continuous with the first source non-conductivity-induced portion 40α. Therefore, even when the first interlayer insulating film 35 is formed, the first intermediate non-conductivity-induced portion 42α, which is a portion overlapping the first non-overlapping insulating portion 33Cα of the semiconductor film 32, is not in direct contact with the first interlayer insulating film 35. However, since the first interlayer insulating film 35 is in contact with the first source non-conductivity-induced portion 40α continuous with the first intermediate non-conductivity-induced portion 42α, the first intermediate non-conductivity-induced portion 42α is also reduced, and as a result, the first intermediate non-conductivity-induced portion 42α is made conductive to some extent to become the first high-resistance portion 27Fα having a resistance higher than that of the first source region 27Bα. Here, when a signal is supplied to the upper-layer side gate electrode 27E, a channel region is generated in the first semiconductor portion 27Dα, and thus, a signal supplied to the first source region 27Bα is transmitted by the channel region of the first semiconductor portion 27Dα through the first high-resistance portion 27Fα. Since the first high-resistance portion 27Fα is interposed between the first source region 27Bα and the channel region of the first semiconductor portion 27Dα, the occurrence of hot carrier injection is suitably suppressed.

Further, after patterning the second metal film 34, the upper-layer side gate insulating film 33 is patterned. Even when a film residue is generated in the patterning of the second metal film 34, the film residue portion 34R of the second metal film 34 can be removed by subsequently patterning the upper-layer side gate insulating film 33.

### Second Embodiment

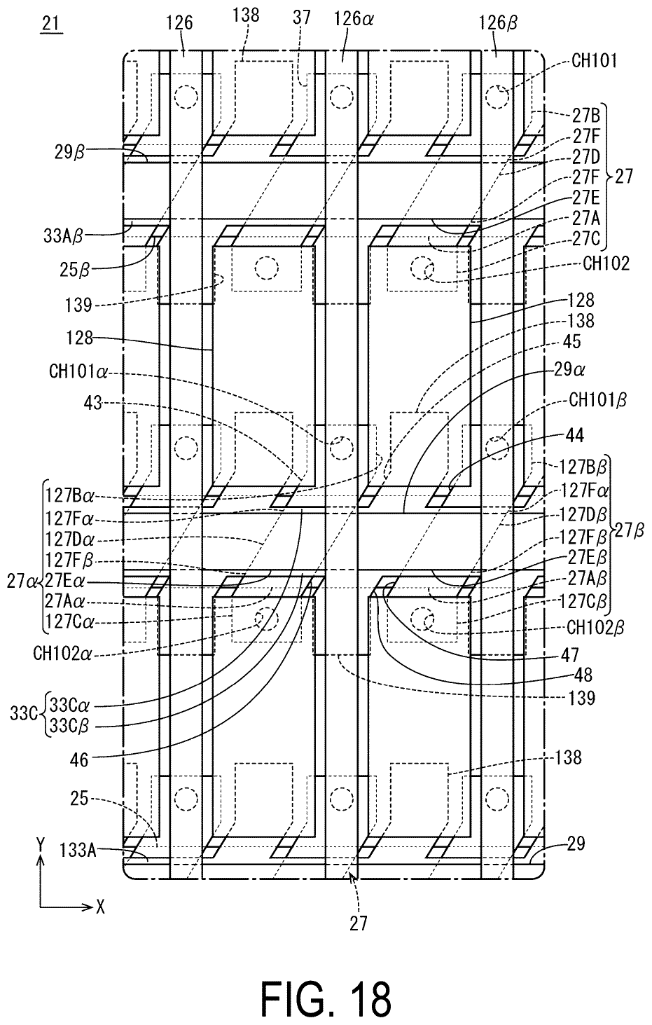

A second embodiment will be described with reference to FIG. 18 to FIG. 20. In this second embodiment, an example in which configurations of a source intervening portion 138 and a drain intervening portion 139 are modified will be described. Further, repetitive descriptions of structures, actions, and effects similar to those of the first embodiment described above will be omitted.

As illustrated in FIG. 18, a first source region 127Bα according to the present embodiment includes a first inclined portion 43 inclined relative to a first source wiring line 126α and a second source wiring line 126B. The first inclined portion 43 extends from a first high-resistance portion 127Fα toward an upper right diagonal side in FIG. 18 and overlaps the first source wiring line 126α. A portion of the first source region 127Bα continuous with an extended tip end portion of the first inclined portion 43 extends in parallel with the first source wiring line 126α and is connected to the first source wiring line 126α through a first source contact hole CH101α.

Similar to the first source region 127Bα, a second source region 127Bβ has a second inclined portion 44 parallel to the first inclined portion 43 as illustrated in FIG. 18. The second inclined portion 44 extends from the first high-resistance portion 127Fα toward the upper right diagonal side in FIG. 18 and overlaps the second source wiring line 126B. A portion of the second source region 127Bβ continuous with the extended tip end portion of the second inclined portion 44 extends in parallel with the second source wiring line 126 and is connected to the second source wiring line 126β through the second source contact hole CH101β.

Then, as illustrated in FIG. 18, the source intervening portion 138 includes a third inclined portion 45 parallel to the first inclined portion 43 and the second inclined portion 44. The third inclined portion 45 extends toward the upper right diagonal side in FIG. 18 from a linear insulating portion 133A, and is interposed between the first inclined portion 43 and the second inclined portion 44. The source intervening portion 138 is disposed such that a portion continuous with the extended tip end portion of the third inclined portion 45 extends along the Y-axis direction and is interposed between a portion of the first source region 127Bα connected to the first source wiring line 126α and a portion of the second source region 127Bβ connected to the second source wiring line 126B. According to the present embodiment, as compared with the first embodiment in which the first source region 27Bα is bent in an L-shape from the first source contact hole CH1α to the first semiconductor portion 27Dα (see FIG. 5), a distance of the first source region 127Bα from the first source contact hole CH101α to the first semiconductor portion 127Dα becomes shorter. As a result, it is possible to increase a pattern density of the structure made of the semiconductor film 132 and at the same time, to keep the first source region 127Bα and the second source region 127Bβ in the electrically non-connected state with high reliability by the source intervening portion 138.

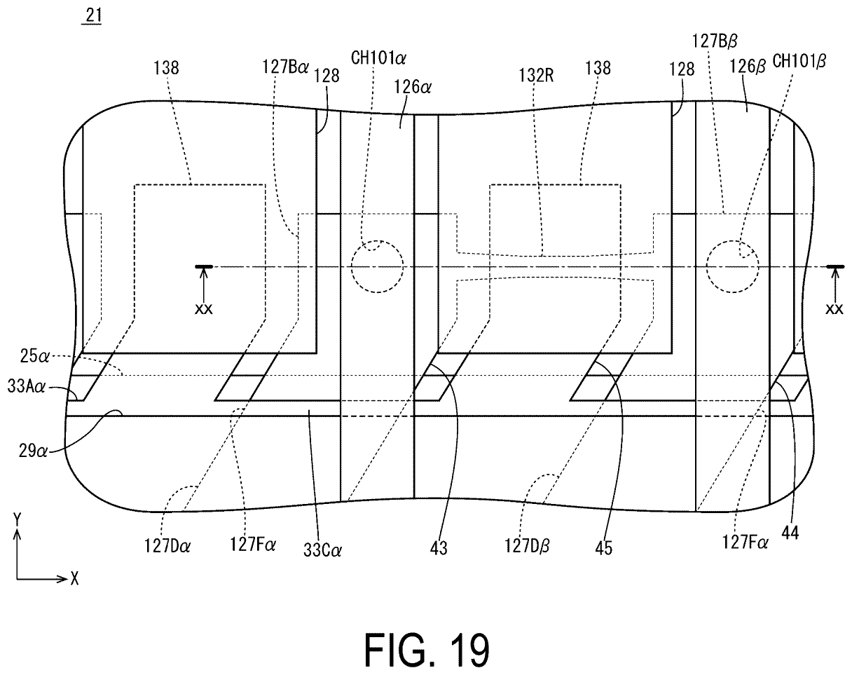

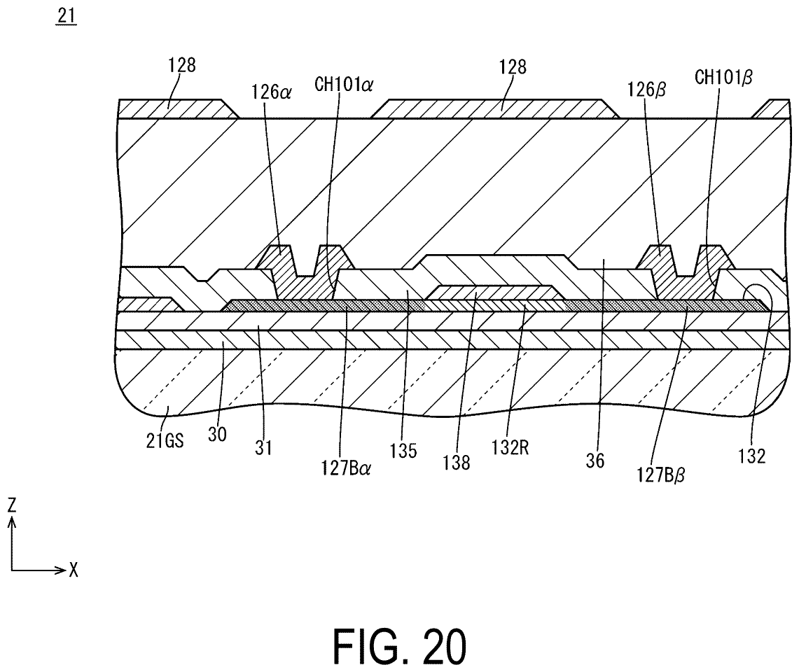

Specifically, as illustrated in FIG. 19 and FIG. 20, the first source region 127Bα and the second source region 127Bβ may be mechanically continuous with each other by the film residue portion 132R when a film residue is generated at the semiconductor film 132. Even in this case, since the source intervening portion 138 is disposed between the first source region 127Bα and the second source region 127Bβ, the source intervening portion 138 is layered (disposed to be overlapped) on the upper layer side of the film residue portion 132R. Therefore, the first interlayer insulating film 135 containing the reducing agent can be prevented from coming into contact with the film residue portion 132R. Thus, the film residue portion 132R is not reduced and is prevented from being made conductive.

As illustrated in FIG. 18, a first drain region 127Cα according to the present embodiment includes a fourth inclined portion 46 inclined relative to the first source wiring line 126α and the second source wiring line 126β. The fourth inclined portion 46 extends from a second high-resistance portion 127Fβ toward a lower left diagonal side illustrated in FIG. 18. In the first drain region 127Cα, a portion continuous with the extended tip end portion of the fourth inclined portion 46 extends in parallel with the first source wiring line 126α and is connected to a pixel electrode 128 through a first drain contact hole CH102α.

Similar to the first drain region 127Cα, as illustrated in FIG. 18, a second drain region 127Cβ includes a fifth inclined portion 47 parallel to the fourth inclined portion 46. The fifth inclined portion 47 extends from the first high-resistance portion 127Fα toward the lower left diagonal side as illustrated in FIG. 18. In the second drain region 127Cβ, a portion continuous with the extended tip end portion of the fifth inclined portion 47 extends in parallel with the second source wiring line 126β and is connected to the pixel electrode 128 through a second drain contact hole CH102β.

As illustrated in FIG. 18, the drain intervening portion 139 includes a sixth inclined portion 48 parallel to the fourth inclined portion 46 and the fifth inclined portion 47. The sixth inclined portion 48 extends from the linear insulating portion 133A toward the lower left diagonal side illustrated in FIG. 18, is interposed between the fourth inclined portion 46 and the fifth inclined portion 47, and overlaps the source wiring line 126. The drain intervening portion 139 is disposed such that a portion continuous with the extended tip end portion of the sixth inclined portion 48 extends along the Y-axis direction and is interposed between a portion of the first drain region 127Cα connected to the pixel electrode 128 and a portion of the second drain region 127Cβ connected to the pixel electrode 128. Since the drain intervening portion 139 having such a configuration is provided, even when a film residue portion mechanically connecting the first drain region 127Cα and the second drain region 127Cβ is generated at the semiconductor film 132, it is possible to avoid a situation where the film residue portion is made conductive.

As described above, according to the present embodiment, the first source wiring line 126α and the second source wiring line 126β are parallel to each other, the first source region 127Bα includes the first inclined portion 43 inclined relative to the first source wiring line 126α and the second source wiring line 126β, the second source wiring region 127Bβ includes the second inclined portion 44 parallel to the first inclined portion 43, and the source intervening portion 138 includes the third inclined portion 45 parallel to the first inclined portion 43 and the second inclined portion 44. Thus, a distance of the first source region 127Bα from the first source contact hole CH101α to a first semiconductor portion 127Dα is shorter than that in the case where the first source region is bent in an L-shape from the first source contact hole CH101α to the first semiconductor portion 127Dα. As a result, it is possible to increase a pattern density of the structure made of the semiconductor film 132 and at the same time, to keep the first source region 127Bα and the second source region 127Bβ in the electrically non-connected state with high reliability by the source intervening portion 138.

### Third Embodiment

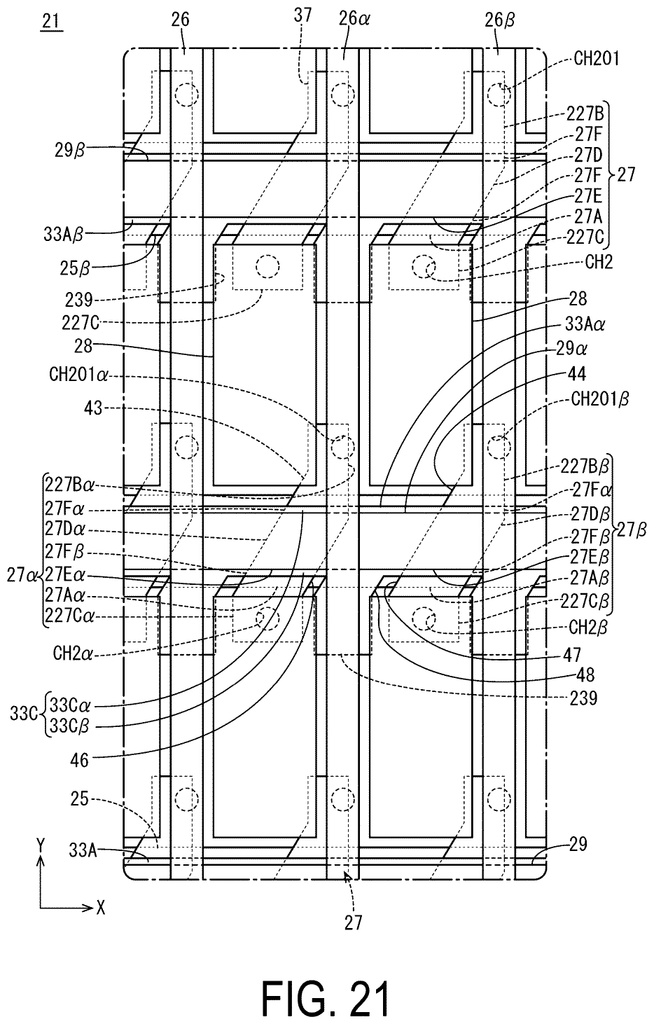

A third embodiment will be described with reference to FIG. 21 to FIG. 23. This third embodiment illustrates a case where the source intervening portion 138 is removed and the configuration of a source region 227B is changed from the second embodiment described above. Further, repetitive descriptions of structures, actions, and effects similar to those of the first embodiment described above will be omitted.

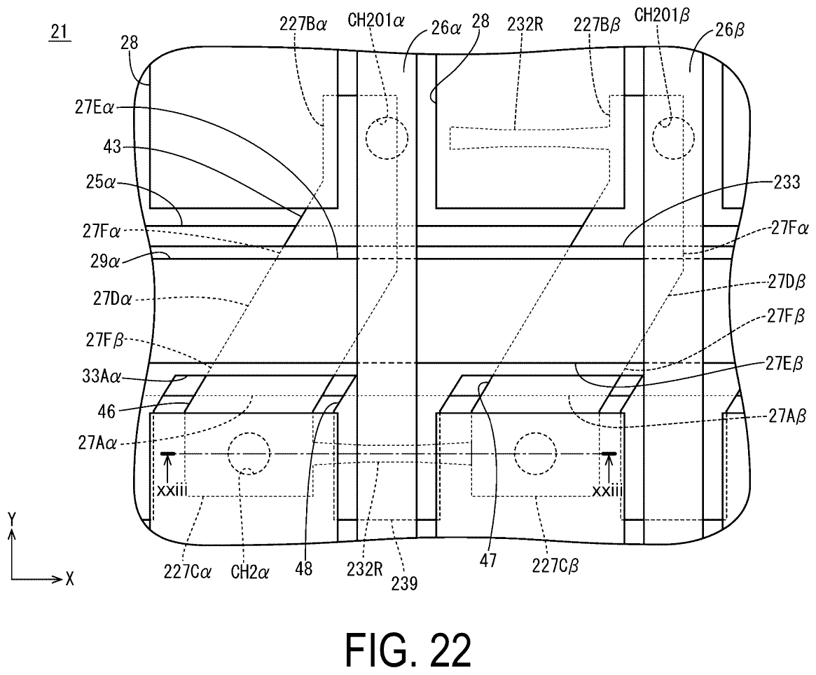

As illustrated in FIG. 21, an upper-layer side gate insulating film 233 according to the present embodiment does not include the source intervening portions 38 and 138 (see FIG. 5 and FIG. 18) described in the first and second embodiments. In addition, the source region 227B according to the present embodiment is formed narrower in width than a drain region 227C, and partially overlaps a source contact hole CH201. To be specific, a first source region 227Bα partially overlaps a first source contact hole CH201α so as not to overlap a portion of the first source contact hole CH201α on a second source region 227Bβ side (right side in FIG. 21). Similarly, the second source region 227Bβ partially overlaps a second source contact hole CH201β so as not to overlap a portion of the second source contact hole CH201β on the side (right side in FIG. 21) opposite to the first source region 227Bα side. In addition, the source region 227B overlaps a range of half or more of the source contact hole CH201 in plan view. According to the present embodiment, an interval between the first source region 227Bα and the second source region 227Bβ is larger than that in the case where the first source regions 27Bα and 127Bα overlap the entire first source contact holes CH1α and CH101α (see FIG. 5 and FIG. 18) as in the first and second embodiments described above. Therefore, even with the configurations where the source intervening portions 38 and 138 are not provided as in the present embodiment, as illustrated in FIG. 22, when a film residue is generated at a semiconductor film 232, a film residue portion 232R is less likely to be mechanically continuous with the first source region 227Bα and the second source region 227Bβ.

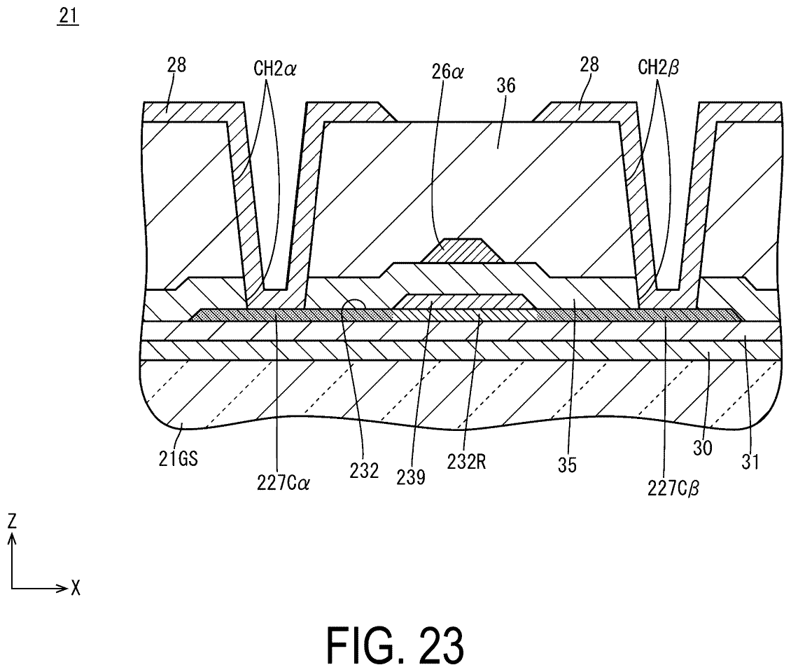

On the other hand, since the drain region 227C is formed to be larger in width than the source region 227B as illustrated in FIG. 22 and FIG. 23, when a film residue is generated at the semiconductor film 232, a situation where the film residue portion 232R is continuous with a first drain region 227Cα and a second drain region 227Cβ is relatively likely to occur. In this regard, since a drain intervening portion 239 is interposed between the first drain region 227Cα and the second drain region 227Cβ, even when the film residue portion 232R mechanically connecting the first drain region 227Cα and the second drain region 227Cβ is generated at the semiconductor film 232, it is possible to avoid a situation in which the film residue portion 232R is made conductive.

As described above, according to the present embodiment, the first source region 227Bα partially overlaps the first source contact hole CH201α so as not to overlap a portion of the first source contact hole CH201α on the second source region 227Bβ side. An interval between the first source region 227Bα and the second source region 227Bβ is larger than that in the case where the first source region overlaps the entire first source contact hole CH201α. As a result, even when a film residue is generated at the semiconductor film 232, a situation in which the film residue portion 232R is mechanically continuous with the first source region 227Bα and the second source region 227Bβ is less likely to occur.

### Fourth Embodiment

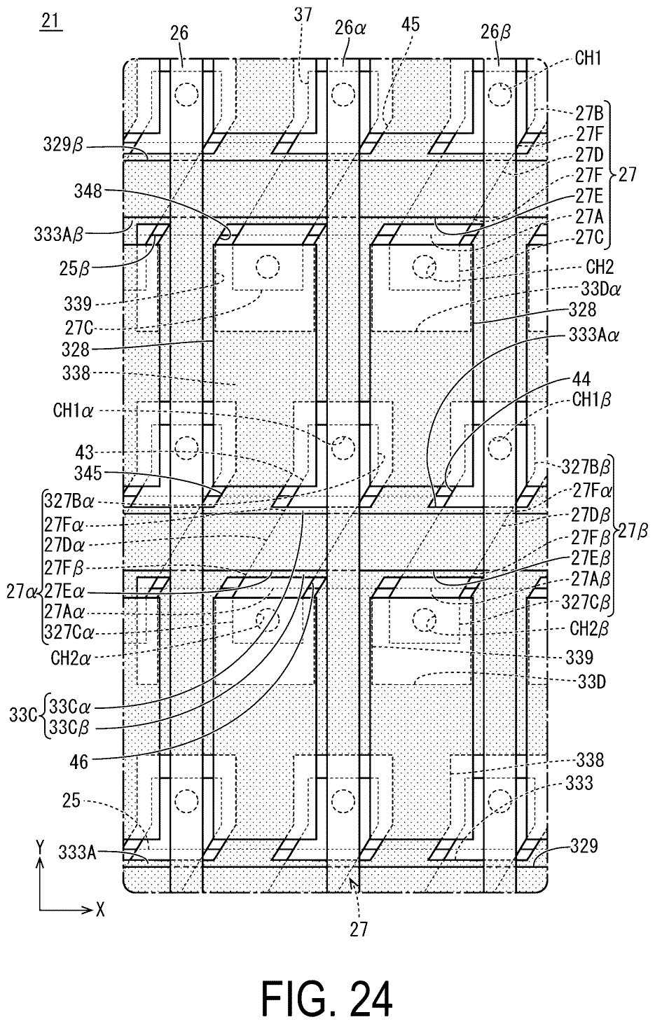

A fourth embodiment will be described with reference to FIG. 24. In the fourth embodiment, a case will be described in which the configuration of the upper-layer side gate insulating film 33 is changed from the second embodiment. Further, repetitive descriptions of structures, actions, and effects similar to those of the second embodiment described above will be omitted.

As illustrated in FIG. 24, the upper-layer side gate insulating film 33 according to the present embodiment includes a pixel-transverse insulating portion 33D extending along the X-axis direction so as to cross a pixel electrode 328. Specifically, the pixel-transverse insulating portion 33D crosses a portion, on a central side, of the pixel electrode 328 in a longitudinal direction (Y-axis direction), and is parallel to a linear insulating portion 333A. The pixel-transverse insulating portion 33D includes a first pixel-transverse insulating portion 33Dα sandwiched between a first linear insulating portion 333Aα and a second linear insulating portion 333Aβ. Each of a source intervening portion 338 and a drain intervening portion 339 is configured to be continuous with the pixel-transverse insulating portion 33D. Specifically, in the source intervening portion 338, an extended tip end portion of a third inclined portion 345 extending from the first linear insulating portion 333Aα further extends along the Y-axis direction and is continuous with the first pixel-transverse insulating portion 33Dα. In the drain intervening portion 339, an extended tip end portion of a sixth inclined portion 348 extending from the second linear insulating portion 333Aβ further extends along the Y-axis direction and is continuous with the first pixel-transverse insulating portion 33Dα.

As described above, the source intervening portion 338 is continuous from the first linear insulating portion 333Aα to the second linear insulating portion 333Aβ through the first pixel-transverse insulating portion 33Dα and the drain intervening portion 339. Accordingly, since a region on a first source region 327Bα side and a region on a second source region 327Bβ side are partitioned by the source intervening portion 338, the first source region 327Bα and the second source region 327Bβ are maintained in the electrically non-connected state with higher reliability. In addition, the drain intervening portion 339 is continuous from the second linear insulating portion 333Aβ to the first linear insulating portion 333Aα through the first pixel-transverse insulating portion 33Dα and the source intervening portion 338. Accordingly, since a region on the first drain region 327Cα side and a region on a second drain region 327Cβ side are partitioned by the drain intervening portion 339, a first drain region 327Cα and the second drain region 327Cβ are maintained in the electrically non-connected state with higher reliability.

As described above, according to the present embodiment, a second upper-layer side gate wiring line (second wiring line) 329β constituted by the second metal film 34, disposed at a position spaced apart from a first upper-layer side gate wiring line 329α in a second direction intersecting a first direction, and extending along the first direction, and a second linear insulating portion 333Aβ constituted by the upper-layer side gate insulating film 333, extending along the first direction, and overlapping the second upper-layer side gate wiring line 329β are provided, and the source intervening portion 338 is continuous with the second linear insulating portion 333Aβ. In this way, since the region on the first source region 327Bα side and the region on the second source region 327Bβ side are partitioned by the source intervening portion 338, the first source region 327Bα and the second source region 327Bβ are maintained in the electrically non-connected state with higher reliability.

### Fifth Embodiment

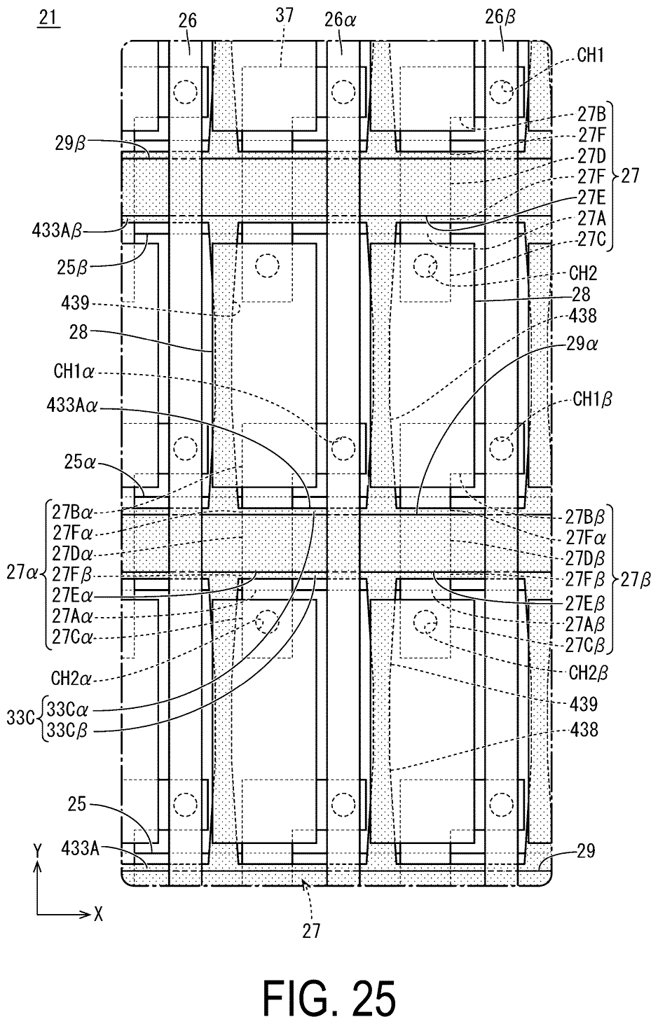

A fifth embodiment will be described with reference to FIG. 25. This fifth embodiment illustrates a case in which configurations of a source intervening portion 438 and a drain intervening portion 439 are changed from those in the first embodiment described above, similar to the fourth embodiment. Note that redundant descriptions of structures, actions, and effects similar to those of the first and fourth embodiments described above will be omitted.

As illustrated in FIG. 25, in the source intervening portion 438 according to the present embodiment, an extended tip end portion extending from a first linear insulating portion 433Aα along the Y-axis direction is connected to the drain intervening portion 439 continuous with a second linear insulating portion 433Aβ. Similarly, in the drain intervening portion 439, the extended tip end portion extending from the first linear insulating portion 433Aα along the Y-axis direction is connected to the source intervening portion 438 continuous with the linear insulating portion 433A positioned on the side opposite to the second linear insulating portion 433Aβ side with respect to the first linear insulating portion 433Aα. According to the above-described configuration, actions and effects similar to those of the fourth embodiment described above can be achieved.

### Sixth Embodiment

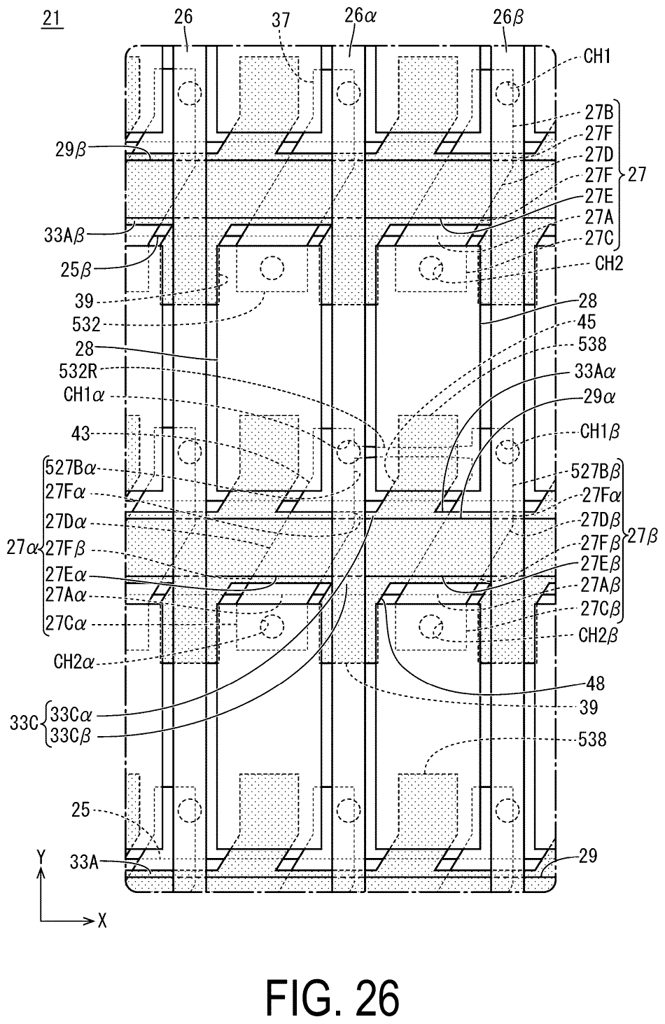

A sixth embodiment will be described with reference to FIG. 26. This sixth embodiment illustrates a case in which a source intervening portion 538 is added to the third embodiment described above. Note that redundant descriptions of structures, actions, and effects similar to those of the third embodiment described above will be omitted.

As illustrated in FIG. 26, the source intervening portion 538 is interposed between a first source region 527Bα and a second source region 527Bβ according to the present embodiment. Here, as described in the third embodiment, although the first source region 527Bα and the second source region 527Bβ are formed in a narrow width shape, a film residue portion 532R generated in a semiconductor film 532 may be mechanically continuous with the first source region 527Bα and the second source region 527Bβ. Even in this case, since the source intervening portion 538 is interposed between the first source region 527Bα and the second source region 527Bβ, it is possible to avoid a situation in which the film residue portion 532R continuous with the first source region 527Bα and the second source region 527Bβ is made conductive.

### Seventh Embodiment

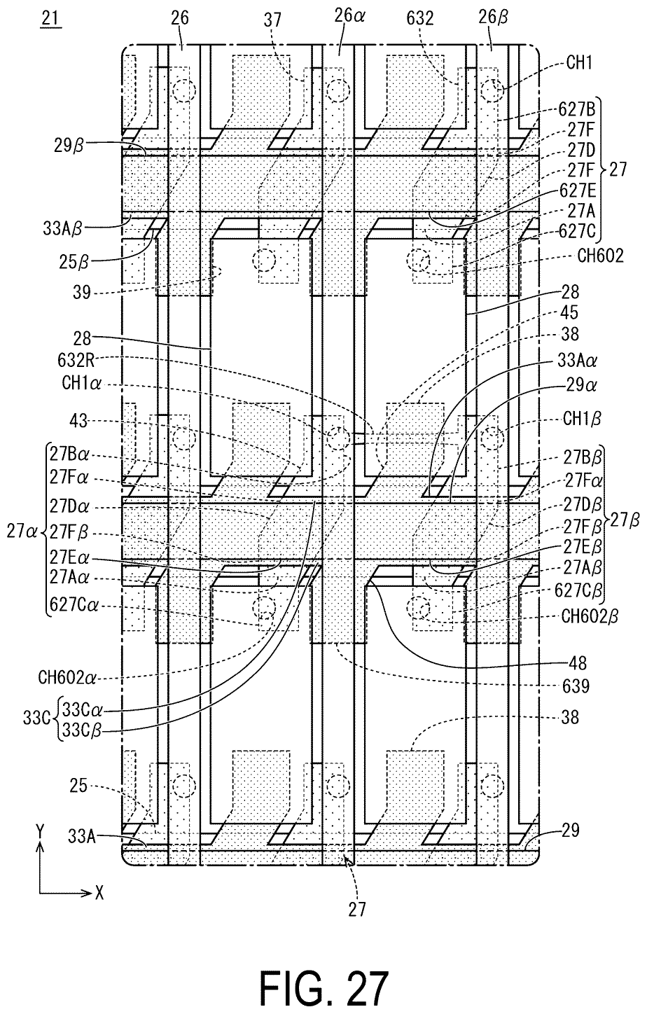

A seventh embodiment will be described with reference to FIG. 27. In the seventh embodiment, a case will be described in which a configuration of a drain region 627C is changed from the third embodiment described above. Note that redundant descriptions of structures, actions, and effects similar to those of the third embodiment described above will be omitted.

As illustrated in FIG. 26, the drain region 627C has the same width as a source region 627B. Then, the drain region 627C partially overlaps a drain contact hole CH602. To be specific, a first drain region 627Cα partially overlaps a first drain contact hole CH602α so as not to overlap a portion of the first drain contact hole CH602α on the side (left side in FIG. 26) opposite to a second drain region 627Cβ side. Similarly, the second drain region 627Cβ partially overlaps a second drain contact hole CH602β so as not to overlap a portion of the second drain contact hole CH602β on the first drain region 627Cα side (left side in FIG. 26). Further, the drain region 627C overlaps a range of half or more of the drain contact hole CH602 in plan view. According to the present embodiment, an interval between the first drain region 627Cα and the second drain region 627Cβ is larger than those in the cases where the first drain regions CH2α and CH102α overlap the entire first drain contact holes 27Cα and 127Cα, respectively, (see FIG. 5 and FIG. 18) as in the first and second embodiments described above. Therefore, when a film residue is generated at a semiconductor film 632, a situation in which the film residue portion 632R is mechanically continuous with the first drain region 627Cα and the second drain region 627Cβ is less likely to occur. Moreover, since a drain intervening portion 639 is interposed between the first drain region 627Cα and the second drain region 627Cβ, it is possible to avoid a situation in which the film residue portion 632R continuous with the first drain region 627Cα and the second drain region 627Cβ is made conductive.

### Eighth Embodiment

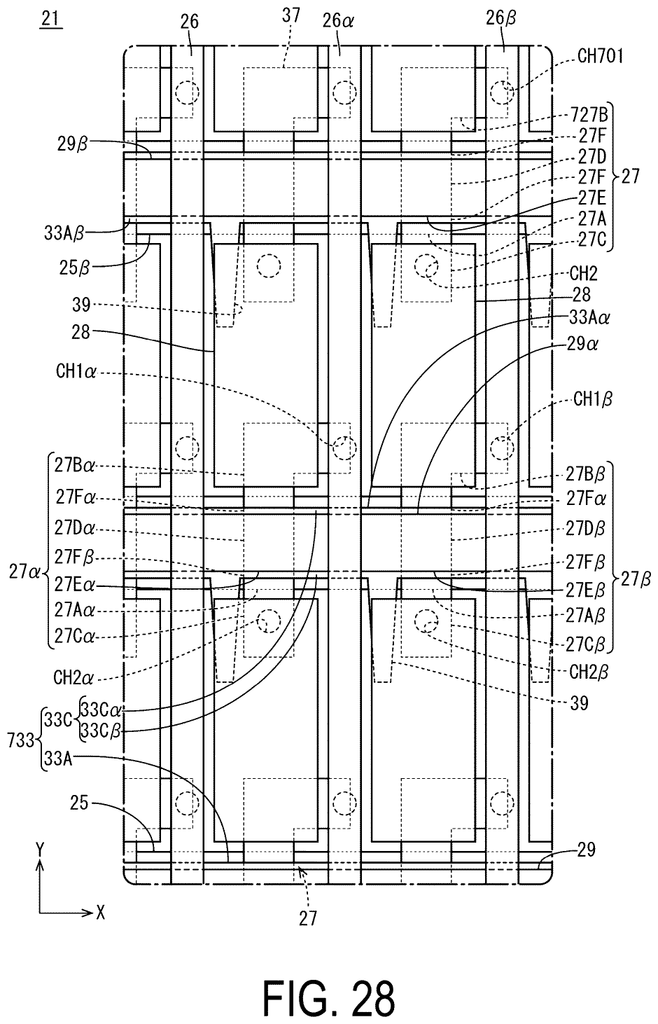

An eighth embodiment will be described with reference to FIG. 28. This eighth embodiment illustrates a case in which the configuration described in the third embodiment described above is adopted to the configuration described in the first embodiment described above. Note that redundant descriptions of structures, actions, and effects similar to those of the third embodiment described above will be omitted.

As illustrated in FIG. 28, an upper-layer side gate insulating film 733 according to the present embodiment does not include the source intervening portions 38 and 138 (see FIG. 5 and FIG. 18) respectively described in the first and second embodiments. In addition, a source region 727B according to the present embodiment is formed such that a portion thereof extending along the X-axis direction is shorter than the source regions 27B and 127B (see FIG. 5 and FIG. 18) respectively described in the first and second embodiments, and as a result, the source region 727B partially overlaps a source contact hole CH701. Even with such a configuration, actions and effects similar to those in the above-described third embodiment can be achieved.

### Ninth Embodiment

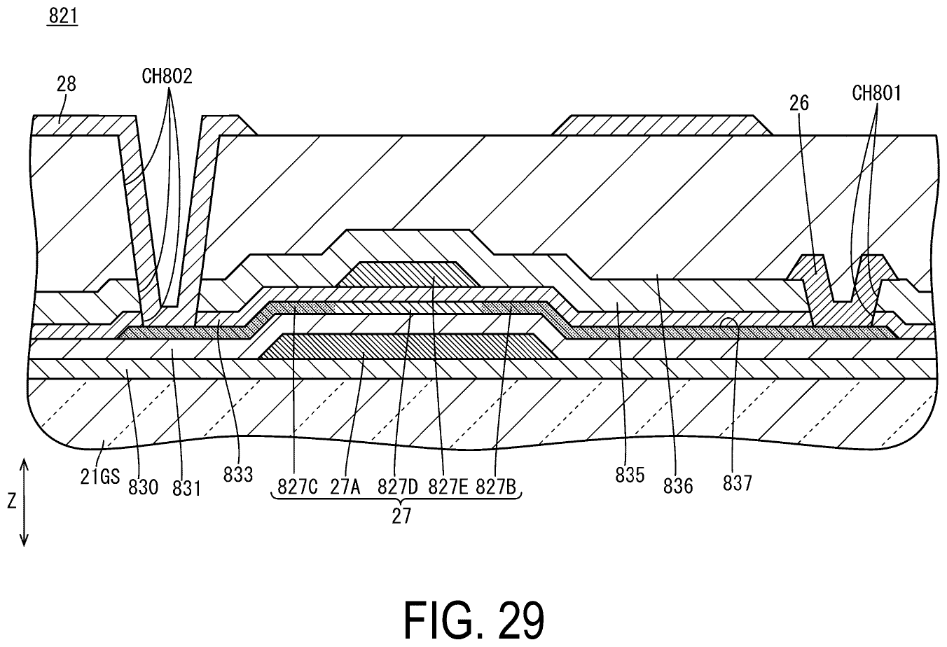

A ninth embodiment will be described with reference to FIG. 29 to FIG. 35. In the ninth embodiment, a case will be described in which configurations of an upper-layer side gate insulating film 833 and a source intervening portion 838 and a method for manufacturing an array substrate 821 are changed from the first embodiment. Further, repetitive descriptions of structures, actions, and effects similar to those of the first embodiment described above will be omitted.

As illustrated in FIG. 29, the upper-layer side gate insulating film 833 according to the present embodiment is formed in a substantially solid-like shape in a main surface of the array substrate 821. The upper-layer side gate insulating film 833 formed in the solid-like shape covers substantially the entire region of a semiconductor pattern portion 837. Therefore, a first interlayer insulating film 835 is not in direct contact with the semiconductor pattern portion 837. Accordingly, in the semiconductor pattern portion 837, even though the first interlayer insulating film 835 contains a reducing agent, the semiconductor pattern portion 837 is prevented from being reduced and made conductive by the reducing agent. Therefore, the semiconductor pattern portion 837 according to the present embodiment does not include the high-resistance portion 27F (see FIG. 6) described in the first embodiment. Portions of the semiconductor pattern portion 837 that do not overlap an upper-layer side gate electrode 827E are a source region 827B and a drain region 827C. Additionally, the upper-layer side gate insulating film 833 does not constitute the source intervening portion 838. Further, in the upper-layer side gate insulating film 833, an opening is formed so as to communicate with a source contact hole CH801 formed as an opening in the first interlayer insulating film 835, and an opening is formed so as to communicate with a drain contact hole CH802 formed as an opening in the first interlayer insulating film 835 and a flattening film 836.

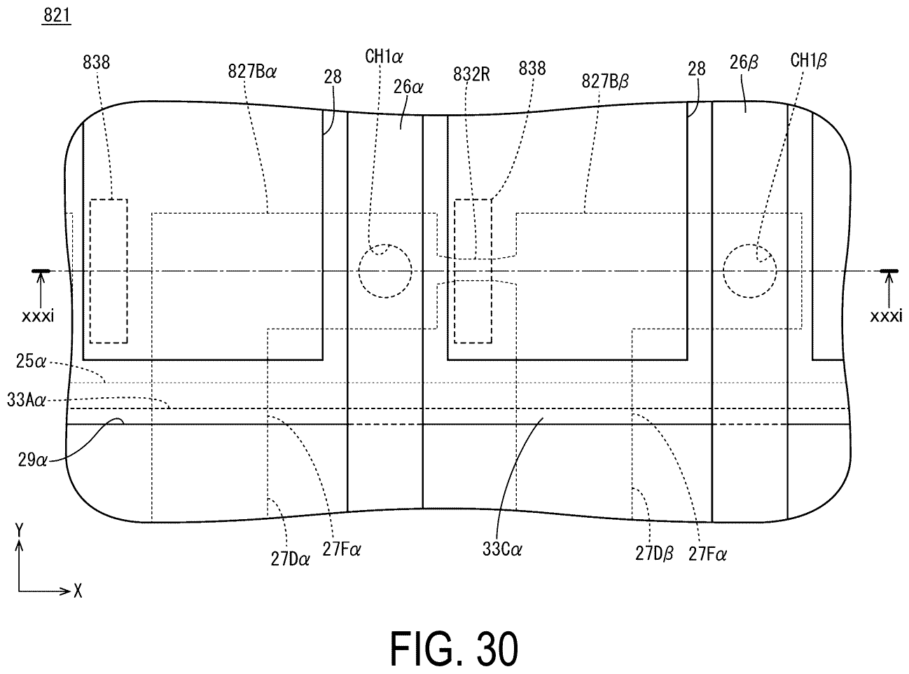

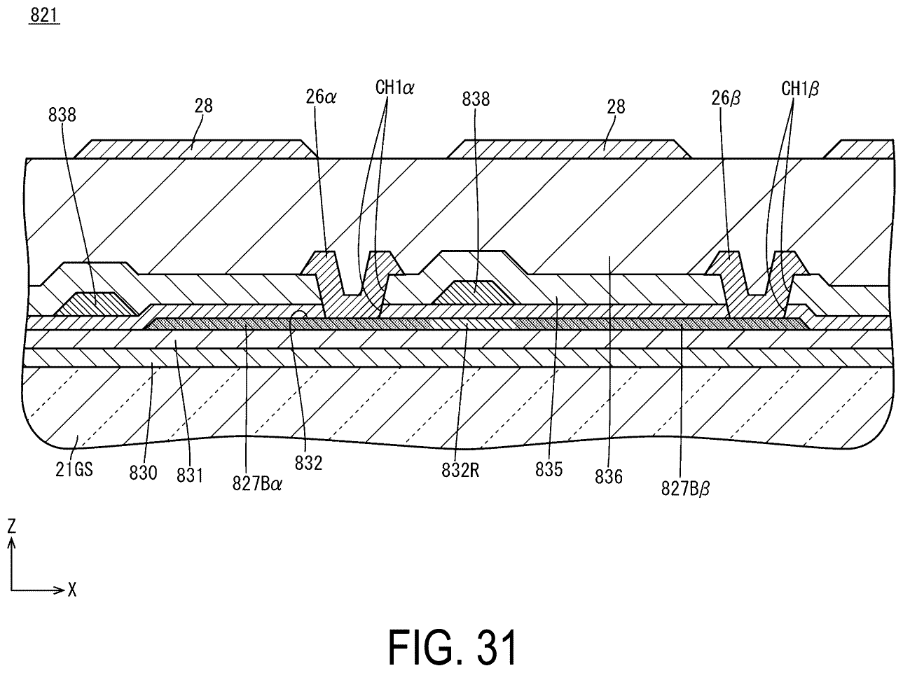

As illustrated in FIG. 30 and FIG. 31, the source intervening portion 838 is constituted by a portion of a second metal film 834 different from an upper-layer side gate wiring line 829 (including the upper-layer side gate electrode 827E). The source intervening portion 838 is formed in island shapes physically separated from the upper-layer side gate wiring line 829. Thus, the source intervening portion 838 is electrically isolated from the upper-layer side gate wiring line 829. Thus, the source intervening portion 838 constituted by the second metal film 834 is disposed between a first source region 827Bα and a second source region 827Bβ. Therefore, even when a film residue is generated at the semiconductor film 832 and a film residue portion 832R is present continuous with the first source region 827Bα and the second source region 827Bβ, the source intervening portion 838 overlaps the film residue portion 832R, thus the film residue portion 832R of the semiconductor film 832 can be prevented from being made conductive. In particular, since the source intervening portion 838 according to the present embodiment is made of a metal material, it is highly reliable that the film residue portion 832R of the semiconductor film 832 is prevented from being made conductive. Note that although not illustrated, the drain intervening portion 39 is also constituted by the second metal film 834.

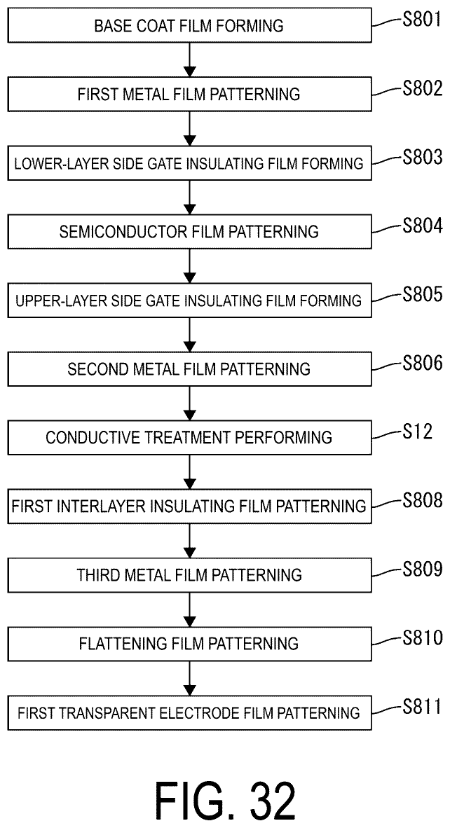

The present embodiment has the structure described above, and next, a method for manufacturing the array substrate 821 will be described. As illustrated in FIG. 32, the method for manufacturing the array substrate 821 includes at least base coat film forming S801 of forming the base coat film 830, first metal film patterning S802 of forming and patterning the first metal film, lower-layer side gate insulating film forming S803 of forming the lower-layer side gate insulating film 831, semiconductor film patterning S804 of forming and patterning the semiconductor film 832, upper-layer side gate insulating film forming S805 of forming the upper-layer side gate insulating film 833, second metal film patterning S806 of forming and patterning the second metal film 834, conductive treatment S12 of selectively performing conductive treatment on the semiconductor film 832, first interlayer insulating film patterning S808 of forming and patterning the first interlayer insulating film 835, third metal film patterning S809 of forming and patterning the third metal film, flattening film patterning S810 of forming and patterning the flattening film 836, and first transparent electrode film patterning S811 of forming and patterning the first transparent electrode film. The conductive treatment S12 among the processes described above will be described below in detail.

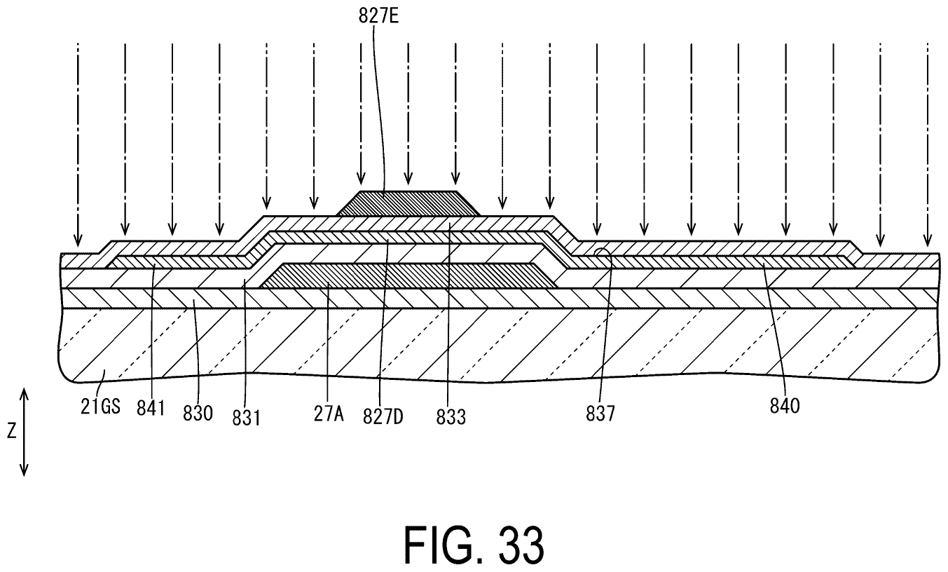

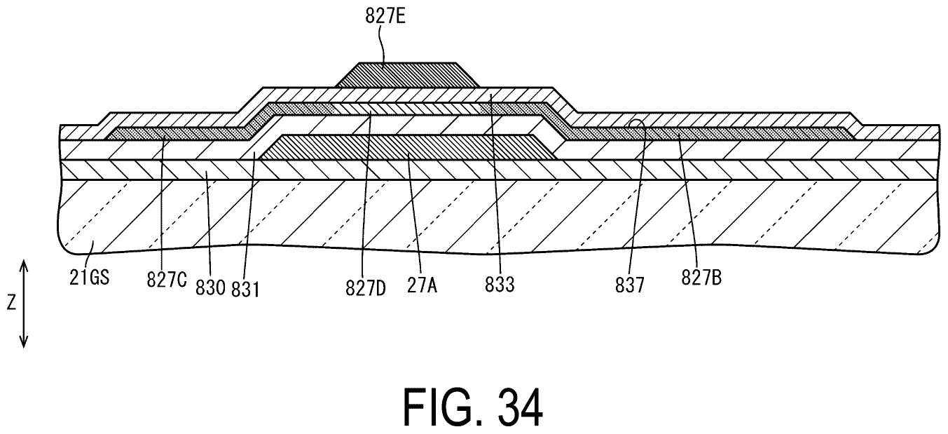

After the upper-layer side gate electrode 827E and the like constituted by the second metal film 834 are formed by performing the second metal film patterning S806, the conductive treatment S12 is performed. To be more specific, in the conductive treatment S12, as illustrated in FIG. 33, treatment of doping (injecting) accelerated impurity ions into the semiconductor pattern portion 837 of the semiconductor film 832 is performed as the conductive treatment. In FIG. 33, a direction in which the impurity ions are doped is indicated by alternating dotted-dashed lines. The impurity ions are selectively doped into a source non-conductivity-induced portion 840 and a drain non-conductivity-induced portion 841, which are portions not covered with the upper-layer side gate electrode 827E constituted by the second metal film 834, of the semiconductor pattern portion 837 of the semiconductor film 832 before being made conductive. On the other hand, a semiconductor portion 827D, which is a portion covered with the upper-layer side gate electrode 827E, of the semiconductor pattern portion 837 of the semiconductor film 832 before being made conductive, is not doped with the impurity ions. As illustrated in FIG. 34, the source non-conductivity-induced portion 840 and the drain non-conductivity-induced portion 841, of the semiconductor pattern portion 837 of the semiconductor film 832, are made conductive by being doped with the impurity ions and thus become the source region 827B and the drain region 827C.

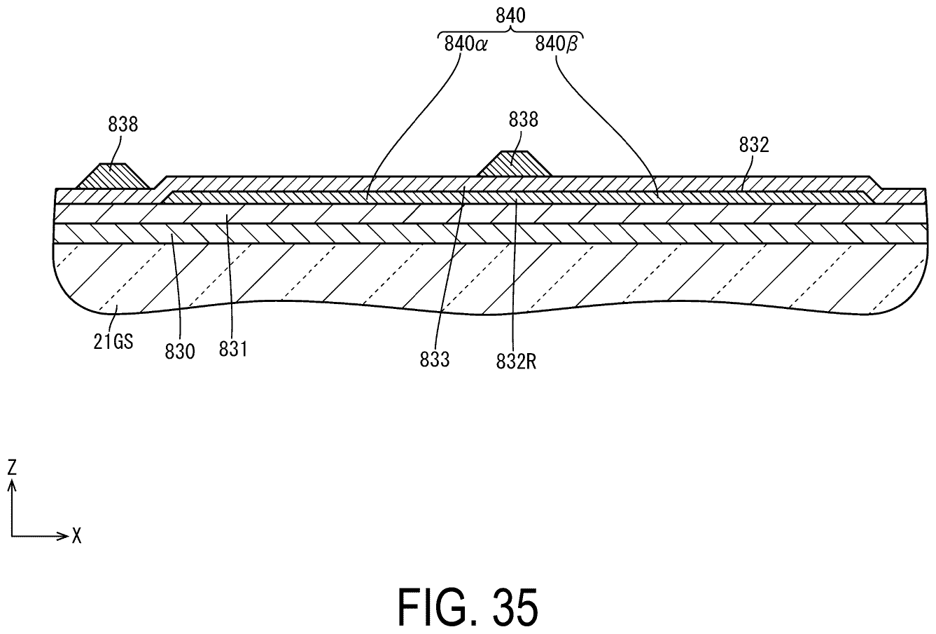

On the other hand, when a film residue is generated at the semiconductor pattern portion 837 of the semiconductor film 832 patterned through the semiconductor film patterning S804, a first source non-conductivity-induced portion 840α and a second source non-conductivity-induced portion 840β may be mechanically continuous with each other by the film residue portion 832R as illustrated in FIG. 35. Even in this case, since the source intervening portion 838 of the second metal film 834 patterned through the second metal film patterning S806 is disposed between the first source non-conductivity-induced portion 840α and the second source non-conductivity-induced portion 840β, the source intervening portion 838 is layered (disposed to be overlapped) on the upper layer side of the film residue portion 832R with the upper-layer side gate insulating film 833 interposed therebetween. Therefore, even when the process of doping the accelerated impurity ions is performed in the conductive treatment S12, the film residue portion 832R of the semiconductor film 832 is masked by the source intervening portion 838, so that the impurity ions are less likely to be injected into the film residue portion 832R. Thus, the film residue portion 832R of the semiconductor film 832 is prevented from being made conductive. As described above, even when the film residue is generated at the semiconductor film 832, the first source region 827Bα and the second source region 827Bβ are maintained in the electrically non-connected state with high reliability.

As described above, the array substrate 821 according to the present embodiment includes the upper-layer side gate electrode (first electrode) 827E constituted by the second metal film (first conductive film) 834, the upper-layer side gate insulating film (first insulating film) 833 disposed on the lower layer side of the second metal film 834, the first source region (first conductivity-induced portion) 827Bα obtained by making the portion not overlapping the upper-layer side gate electrode 827E, of the semiconductor film 832 disposed on the lower layer side of the upper-layer side gate insulating film 833, conductive, the second source region (second conductivity-induced portion) 827Bβ obtained by making the portion of the semiconductor film 832 being other than the first source region 827Bα and not overlapping the upper-layer side gate electrode 827E conductive, a first semiconductor portion 827Dα constituted by the portion of the semiconductor film 832 overlapping the upper-layer side gate electrode 827E, and the source intervening portion (intervening portion) 838 constituted by the portion of the second metal film 834 being other than the upper-layer side gate electrode 827E and disposed between the first source region 827Bα and the second source region 827Bβ.

The first source region 827Bα and the second source region 827Bβ are portions of the semiconductor film 832 that do not overlap the upper-layer side gate electrode 827E, whereas the first semiconductor portion 827Dα is a portion that overlaps the upper-layer side gate electrode 827E. Here, when a film residue is generated at the semiconductor film 832 in the patterning of the semiconductor film 832, the first source region 827Bα and the second source region 827Bβ may be mechanically continuous with each other by the film residue portion 832R. Even in this case, the source intervening portion 838 constituted by the portion of the second metal film 834 other than the upper-layer side gate electrode 827E is disposed between the first source region 827Bα and the second source region 827Bβ, and thus, overlaps the film residue portion 832R mechanically continuous with the first source region 827Bα and the second source region 827Bβ. Therefore, the film residue portion 832R of the semiconductor film 832 is masked by the overlapped source intervening portion 838, thereby preventing the film residue portion 832R from being made conductive. As a result, even when a film residue is generated at the semiconductor film 832, the first source region 827Bα and the second source region 827Bβ are maintained in an electrically non-connected state with high reliability.

Additionally, the second metal film 834 is made of a metal material, and the source intervening portion 838 is constituted by a portion of the second metal film 834 different from the upper-layer side gate electrode 827E. The source intervening portion 838 constituted by the portion of the second metal film 834 other than the upper-layer side gate electrode 827E is disposed between a first source region 827Bα and the second source region 827Bβ, thereby making it possible to prevent the film residue portion 832R of the semiconductor film 832 continuous with the first source region 827Bα and the second source region 827Bβ from being made conductive. Since the source intervening portion 838 is made of a metal material, it is highly reliable that the film residue portion 832R of the semiconductor film 832 is prevented from being made conductive.

Further, the method for manufacturing the array substrate 821 according to the present embodiment includes forming the semiconductor film 832, patterning the semiconductor film 832, and thus providing the first source non-conductivity-induced portion 840α, the second source non-conductivity-induced portion 840β spaced apart from the first source non-conductivity-induced portion 840α, and the first semiconductor portion 827Dα, forming the upper-layer side gate insulating film 833 on the upper layer side of the semiconductor film 832, forming the second metal film 834 on the upper layer side of the upper-layer side gate insulating film 833, patterning the second metal film 834, and thus providing the upper-layer side gate electrode 827E overlapping the first semiconductor portion 827Dα, and the source intervening portion 838 disposed between the first source non-conductivity-induced portion 840α and the second source non-conductivity-induced portion 840β, and performing the conductive treatment on the semiconductor film 832 by using the second metal film 834 as the mask and making the semiconductor film 832 conductive, making the first source non-conductivity-induced portion 840α and the second source non-conductivity-induced portion 840β, which do not overlap the upper-layer side gate electrode 827E and the source intervening portion 838, conductive, and thus changing the first source non-conductivity-induced portion 840α and the second source non-conductivity-induced portion 840β into the first source region 827Bα and the second source region 827Bβ, respectively.

When a film residue is generated at the semiconductor film 832 in the patterning of the semiconductor film 832, the first source non-conductivity-induced portion 840α and the second source non-conductivity-induced portion 840β may be mechanically continuous with each other by the film residue portion 832R. Even in this case, when the second metal film 834 is patterned, the upper-layer side gate electrode 827E overlapping the first semiconductor portion 827Dα and the source intervening portion 838 disposed between the first source non-conductivity-induced portion 840α and the second source non-conductivity-induced portion 840β are provided, and among these, the source intervening portion 838 overlaps the film residue portion 832R of the semiconductor film 832. Therefore, when the second metal film 834 is used as the mask to make the semiconductor film 832 conductive, the first source non-conductivity-induced portion 840α and the second source non-conductivity-induced portion 840β, which do not overlap the upper-layer side gate electrode 827E and the source intervening portion 838, are made conductive, while the film residue portion 832R of the semiconductor film 832, which overlaps the source intervening portion 838, is prevented from being made conductive. As a result, even when a film residue is generated at the semiconductor film 832, the first source region 827Bα and the second source region 827Bβ are maintained in an electrically non-connected state with high reliability.

### OTHER EMBODIMENTS

The techniques disclosed herein are not limited to the embodiments described above and illustrated in the drawings, and the following embodiments, for example, are also included within the technical scope.

(1) In the configurations described in the first embodiment to the eighth embodiment, the source intervening portions 38, 138, 338, 438, and 538 may be formed in island shapes physically separated from the linear insulating portions 33A, 133A, 333A, and 433A. Similarly, the drain intervening portions 39, 139, 239, 339, 439, and 639 may be formed in island shapes physically separated from the linear insulating portions 33A, 133A, 333A, and 433A.

(2) In the configurations described in the first, fifth, and eighth embodiments, the source intervening portions 38 and 438 may be configured to have a constant width. Similarly, the drain intervening portions 39 and 439 may be configured to have a constant width.

(3) In the configurations described in the second to fourth, sixth, seventh, and ninth embodiments, the source intervening portions 138, 338, 538, and 838 may have a configuration in which a width dimension is changed depending on the position in the Y-axis direction. Similarly, the drain intervening portions 139, 239, 339, and 639 may have a configuration in which the width dimension is changed depending on the position in the Y-axis direction.

(4) In addition to (2) and (3) described above, the specific planar shapes of the source intervening portions 38, 138, 338, 438, 538, and 838 can be changed as appropriate. Similarly, the specific planar shapes of the drain intervening portions 39, 139, 239, 339, 439, and 639 can be changed as appropriate.

(5) The array substrates 21 and 821 do not need to include the upper-layer side gate wiring lines 29, 329, and 829. Even in this case, by connecting the upper-layer side gate electrodes 27E, 627E, and 827E to the lower-layer side gate electrode 27A or to the lower-layer side gate wiring line 25, it is possible to supply a scanning signal to the upper-layer side gate electrodes 27E, 627E, and 827E at the same timing as the supply of a scanning signal to the lower-layer side gate electrode 27A.

(6) The array substrates 21 and 821 do not need to include the lower-layer side gate wiring line 25. Even in this case, by connecting the lower-layer side gate electrode 27A to the upper-layer side gate electrodes 27E, 627E, and 827E or to the upper-layer side gate wiring lines 29, 329, and 829, it is possible to supply a scanning signal to the lower-layer side gate electrode 27A at the same timing as the supply of a scanning signal to the upper-layer side gate electrodes 27E, 627E, and 827E.

(7) The TFT 27 does not need to include the lower-layer side gate electrode 27A. That is, the TFT 27 may be a top gate type instead of a double gate type. Along with the omission of the lower-layer side gate electrode 27A, the array substrates 21 and 821 can be configured not to include the lower-layer side gate wiring line 25. In addition, the first metal film can be omitted in the array substrates 21 and 821.

(8) In the configurations described in the first embodiment to the eighth embodiment, the upper-layer side gate insulating films 33, 233, 333, and 733 may include the first insulating portion 33B and the non-overlapping insulating portion 33C without the linear insulating portions 33A, 133A, 333A, and 433A. That is, the upper-layer side gate insulating films 33, 233, 333, and 733 may be constituted by the first insulating portion 33B and the non-overlapping insulating portion 33C that are scattered in island shapes for the respective TFTs 27.

(9) When the pixel electrode 28 and the source wiring lines 26 and 126 are constituted by each part of the conductivity-induced portion in the semiconductor films 32, 132, 232, 532, 632, and 832, an intervening portion may be provided so as to be interposed between the pixel electrode 28 serving as the “first conductivity-induced portion” and the source wiring line 26 or 126 serving as the “second conductivity-induced portion”.

(10) The specific method for making the semiconductor films 32, 132, 232, 532, 632, and 832 conductive can be appropriately changed in addition to the method described above.

(11) A source driver may be attached to the array substrates 21 and 821 instead of the second circuit portion 14B.

(12) A source driver may be attached to the flexible substrate 13 instead of the second circuit portion 14B.

(13) A gate driver may be attached to the array substrates 21 and 821 instead of the first circuit portion 14A.

(14) Each of the semiconductor films 32, 132, 232, 532, 632, and 832 may be an amorphous silicon thin film or a polycrystalline silicon thin film.

(15) The liquid crystal panel 11 may be a reflective type or a semi-transmissive type, in addition to a transmissive type. When the liquid crystal panel 11 is the reflective type, the backlight device 12 may be omitted.

(16) In addition to the head-mounted display 10HMD, the disclosure can be applied to, for example, a head-up display, a projector, or the like as a device that enlarges and displays an image displayed on the liquid crystal panel 11 using a lens or the like. The disclosure can be also applied to a display device that does not have an enlarged display function (a television receiver, a tablet terminal, a smartphone, or the like).

(17) Each of the linear insulating portions 33A, 133A, 333A, and 433A may be disposed within a belt-like range having the same width as the lower-layer side gate wiring line 25 and may overlap the entire region of the lower-layer side gate wiring line 25.

(18) In the ninth embodiment, after the upper-layer side gate electrode 827E is formed through the second metal film patterning, a photoresist film may be formed and patterned to provide the source intervening portion 838 made of the photoresist film, and the conductive treatment may be performed by using the source intervening portion 838 as a mask. That is, the source intervening portion 838 may be constituted by a photoresist film instead of the second metal film 834. According to such a method, even when the film residue portion 832R is generated at the semiconductor film 832, the source intervening portion 838 overlapping the film residue portion 832R prevents the film residue portion 832R from being made conductive, thereby increasing the reliability that the first source region 827Bα and the second source region 827Bβ are maintained in an electrically non-connected state. Note that the drain intervening portion 839 may also be constituted by a photoresist film as described above.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. An array substrate comprising:
a first electrode constituted by a first conductive film;
a first insulating film disposed on a lower layer side of the first conductive film;
a first conductivity-induced portion formed by making a portion of a semiconductor film disposed on a lower layer side of the first insulating film conductive, the portion not overlapping the first electrode;
a second conductivity-induced portion formed by making a portion of the semiconductor film other than the first conductivity-induced portion conductive, the portion not overlapping the first electrode;
a first semiconductor portion constituted by a portion of the semiconductor film overlapping the first electrode; and
an intervening portion constituted by a portion of the first conductive film other than the first electrode or a part of the first insulating film, the intervening portion being disposed between the first conductivity-induced portion and the second conductivity-induced portion.

2. The array substrate according to claim 1,
wherein the first insulating film includes a first insulating portion overlapping the first electrode and the first semiconductor portion, and
the intervening portion is constituted by a portion of the first insulating film other than the first insulating portion.

3. The array substrate according to claim 2,
wherein the semiconductor film is made of an oxide semiconductor material,
a second insulating film is provided on an upper layer side of the first conductive film and includes a reducing agent,
the second insulating film is in contact with the first conductivity-induced portion and the second conductivity-induced portion,
the first insulating film includes a second insulating portion being continuous with the first insulating portion and not overlapping the first electrode and the first semiconductor portion, and
a first high-resistance portion constituted by a portion of the semiconductor film overlapping the second insulating portion is provided, and the first high-resistance portion is continuous with the first conductivity-induced portion and has a resistance higher than a resistance of the first conductivity-induced portion.

4. The array substrate according to claim 3,
wherein a distance from an end portion of the intervening portion on the first conductivity-induced portion side to an end portion of the intervening portion on the second conductivity-induced portion side is larger than a distance from an end portion of the first high-resistance portion on the first semiconductor portion side to an end portion of the first high-resistance portion on the first conductivity-induced portion side.

5. The array substrate according to claim 2, further comprising:
a first wiring line constituted by the first conductive film, the first wiring line extending along a first direction, the first wiring line including the first electrode; and
a first linear insulating portion constituted by the first insulating film, the first linear insulating portion extending along the first direction, the first linear insulating portion overlapping the first wiring line, and the first linear insulating portion including the first insulating portion,
wherein the first conductivity-induced portion and the second conductivity-induced portion intersect the first wiring line and the first linear insulating portion, and
the intervening portion is continuous with the first linear insulating portion.

6. The array substrate according to claim 5, further comprising:
a second wiring line made of the first conductive film, the second wiring line being disposed at a position spaced apart from the first wiring line in a second direction intersecting the first direction, the second wiring line extending along the first direction; and
a second linear insulating portion constituted by the first insulating film, the second linear insulating portion extending along the first direction, the second linear insulating portion overlapping the second wiring line,
wherein the intervening portion is continuous with the second linear insulating portion.

7. The array substrate according to claim 1,
wherein the first conductive film is made of a metal material, and
the intervening portion is constituted by a portion of the first conductive film other than the first electrode.

8. The array substrate according to claim 1, further comprising:
a second insulating film disposed on an upper layer side of the first conductive film;
a third wiring line constituted by a second conductive film disposed on an upper layer side of the second insulating film, the third wiring line partially overlapping the first conductivity-induced portion; and
a fourth wiring line constituted by a portion of the second conductive film other than the third wiring line, the fourth wiring line partially overlapping the second conductivity-induced portion,
wherein a first contact hole connecting the third wiring line and the first conductivity-induced portion is provided at a position of the second insulating film overlapping both the third wiring line and the first conductivity-induced portion, and
a second contact hole connecting the fourth wiring line and the second conductivity-induced portion is provided at a position of the second insulating film overlapping both the fourth wiring line and the second conductivity-induced portion.

9. The array substrate according to claim 8,
wherein the third wiring line and the fourth wiring line are parallel to each other,
the first conductivity-induced portion includes a first inclined portion inclined relative to the third wiring line and the fourth wiring line,
the second conductivity-induced portion includes a second inclined portion parallel to the first inclined portion, and
the intervening portion includes a third inclined portion parallel to the first inclined portion and the second inclined portion.

10. The array substrate according to claim 8,
wherein the first conductivity-induced portion partially overlaps the first contact hole and thus does not overlap a portion of the first contact hole on the second conductivity-induced portion side.

11. A display device comprising:
the array substrate according to claim 1; and
a counter substrate facing the array substrate.

12. A method for manufacturing an array substrate, the method comprising:
forming a semiconductor film made of an oxide semiconductor material, patterning the semiconductor film, and thus providing a first non-conductivity-induced portion, a second non-conductivity-induced portion spaced apart from the first non-conductivity-induced portion, and a first semiconductor portion;
forming a first insulating film on an upper layer side of the semiconductor film;
forming a first conductive film on an upper layer side of the first insulating film;
patterning the first conductive film, and thus providing a first electrode overlapping the first semiconductor portion;
patterning the first insulating film, and thus providing a first insulating portion overlapping the first electrode and the first semiconductor portion, and an intervening portion disposed between the first non-conductivity-induced portion and the second non-conductivity-induced portion; and
forming a second insulating film including a reducing agent on an upper layer side of the first conductive film, bringing the second insulating film into contact with the first non-conductivity-induced portion and the second non-conductivity-induced portion, making the first non-conductivity-induced portion and the second non-conductivity-induced portion conductive, and thus changing the first non-conductivity-induced portion and the second non-conductivity-induced portion into a first conductivity-induced portion and a second conductivity-induced portion, respectively.

13. The method for manufacturing the array substrate according to claim 12, further comprising:
patterning the first insulating film, and thus providing a second insulating portion not overlapping the first electrode and the first semiconductor portion, the second insulating portion being continuous with the first insulating portion; and
patterning the semiconductor film, and thus providing a third non-conductivity-induced portion overlapping the second insulating portion, the third non-conductivity-induced portion being continuous with the first non-conductive portion,
wherein in the forming of the second insulating film, the third non-conductivity-induced portion becomes a first high-resistance portion having a resistance higher than a resistance of the first conductivity-induced portion.

14. The method for manufacturing the array substrate according to claim 12,
wherein the first insulating film is patterned after the first conductive film is patterned.

15. A method for manufacturing an array substrate comprising:
forming a semiconductor film, patterning the semiconductor film, and thus providing a first non-conductivity-induced portion, a second non-conductivity-induced portion spaced apart from the first non-conductivity-induced portion, and a first semiconductor portion;
forming a first insulating film on an upper layer side of the semiconductor film;
forming a first conductive film on an upper layer side of the first insulating film, patterning the first conductive film, and thus providing a first electrode overlapping the first semiconductor portion and an intervening portion disposed between the first non-conductivity-induced portion and the second non-conductivity-induced portion; and
performing a conductive treatment on the semiconductor film by using the first conductive film as a mask and making the semiconductor film conductive, making the first non-conductivity-induced portion and the second non-conductivity-induced portion not overlapping the first electrode and the intervening portion conductive, and thus changing the first non-conductivity-induced portion and the second non-conductivity-induced portion into a first conductivity-induced portion and a second conductivity-induced portion, respectively.
